(19) United States
(12) Patent Application Publication
(10) Pub. No.: US 2026/0293380 A1
(43) Pub. Date: Sep. 24, 2026

(54) DISPLAY DEVICE AND ELECTRONIC DEVICE

(71) Applicant: Samsung Display Co., Ltd., Yongin-si (KR)

(72) Inventor: Sun PARK, Yongin-si (KR)

(21) Appl. No.: 19/391,988

(22) Filed: Nov. 17, 2025

(30) Foreign Application Priority Data
Mar. 20, 2025 (KR) 10-2025-0035896

(51) Int. Cl. H10H 20/831; H10H 29/39; H10H 29/851

(52) U.S. Cl. CPC H10H 20/8312; H10H 29/39; H10H 29/8514

(57) ABSTRACT

A display device and an electronic device are provided. The display device includes a substrate, a pixel electrode and a common electrode spaced apart from each other on the substrate, a first organic layer that covers at least a portion of the pixel electrode and the common electrode and a light emitting element on the first organic layer and including a conductive layer, a first semiconductor layer, an active layer, a second semiconductor layer, a first contact electrode, and a second contact electrode, wherein the light emitting element further includes, a plurality of holes that penetrate the conductive layer, the first semiconductor layer, and the active layer to expose the second semiconductor layer, wherein the first contact electrode is electrically connected to the conductive layer, and wherein the second contact electrode is electrically connected to the exposed second semiconductor layer.

### CROSS-REFERENCE TO RELATED APPLICATION

The present application claims priority to and the benefit of Korean Patent Application No. 10-2025-0035896, filed on Mar. 20, 2025, in the Korean Intellectual Property Office, the entire content of which is hereby incorporated by reference.

### BACKGROUND

### 1. Field

Embodiments of the present disclosure relates to a display device and an electronic device.

### 2. Description of the Related Art

As the information society develops, the demand for display devices that display images is increasing in various forms. The display device may be a flat panel display device such as a liquid crystal display, a field emission display, a light emitting display, and/or the like.

The light emitting display device may include an organic light emitting display device including an organic light emitting diode (OLED) element as a light emitting element, and a micro light emitting display device including a micro light emitting diode element (hereinafter referred to as a micro light emitting diode element) as a light emitting element. Because the micro light emitting diode element is made of inorganic materials, it has less deterioration issues and a longer lifespan as compared to organic light emitting diode (OLED) elements.

### SUMMARY

Aspects and features of embodiments of the present disclosure provide a display device capable of reducing or minimizing bonding defects of a light emitting element by preventing or reducing the occurrence of air pockets that may be formed by the holes of a flip-type micro LED.

However, aspects of embodiments of the present disclosure are not restricted to the one set forth herein. The above and other aspects of embodiments of the present disclosure will become more apparent to one of ordinary skill in the art to which the present disclosure pertains by referencing the detailed description of the present disclosure given below.

According to one or more embodiments of the present disclosure, a display device includes a substrate, a pixel electrode and a common electrode spaced apart from each other on the substrate, a first organic layer that covers at least a portion of the pixel electrode and the common electrode and a light emitting element arranged on the first organic layer and including a conductive layer (e.g., an electrically conductive layer), a first semiconductor layer, an active layer, a second semiconductor layer, a first contact electrode, and a second contact electrode, wherein the light emitting element further includes, a plurality of holes that penetrate the conductive layer, the first semiconductor layer, and the active layer to expose the second semiconductor layer, wherein the first contact electrode is electrically connected to the conductive layer, and wherein the second contact electrode is electrically connected to the exposed second semiconductor layer.

The light emitting element further includes a protective layer that surrounds a side surface of the conductive layer, the first semiconductor layer, the active layer, and the second semiconductor layer, and on one side of the conductive layer, and including a plurality of openings on one side of the conductive layer, wherein the first contact electrode is on the conductive layer exposed by an opening of the protective layer, and wherein the second contact electrode is provided inside a hole exposed by the opening of the protective layer.

The first contact electrode and the second contact electrode each extend from one side of the light emitting element to a side surface of the light emitting element, and further include a first connection electrode connection the pixel electrode and the first contact electrode, and a second connection electrode connection the common electrode and the second contact electrode.

The first contact electrode directly contacts the first connection electrode at a side of the plurality of semiconductor layers, and the second contact electrode directly contacts the second connection electrode on the side of the plurality of semiconductor layers.

The plurality of holes include a first hole and a second hole, wherein the first hole and the second hole are circular, semicircular, or polygonal in a plane.

The first hole and the second hole are symmetrical to each other.

The display device further includes a filler made of an organic material filled in the hole.

According to one or more embodiments of the present disclosure, a display device includes a substrate, a pixel electrode and a common electrode spaced apart from each other on the substrate, a first conductive bonding pattern (e.g., a first electrically conductive bonding pattern) on the pixel electrode and a second conductive bonding pattern (e.g., a second electrically conductive bonding pattern) on the common electrode, a light emitting element on the first conductive bonding pattern and the second conductive bonding pattern, and including a conductive layer (e.g., an electrically conductive layer), a first semiconductor layer, an active layer, and a second semiconductor layer, a first contact electrode, and a second contact electrode, wherein the light emitting element further includes, a plurality of holes that penetrate the conductive layer, the first semiconductor layer, and the active layer to expose the second semiconductor layer, wherein the first contact electrode is electrically connected to the conductive layer, and wherein the second contact electrode is electrically connected to the exposed second semiconductor layer.

The light emitting element further includes a protective layer that surrounds a side surface of the conductive layer, the first semiconductor layer, the active layer, and the second semiconductor layer, and on one side of the conductive layer, and including a plurality of openings on one side of the conductive layer, wherein the first contact electrode is on the conductive layer exposed by an opening of the protective layer, and wherein the second contact electrode is provided inside a hole exposed by the opening of the protective layer.

The plurality of holes include a first hole and a second hole, wherein the first hole and the second hole are circular, semicircular, or polygonal in a plane.

The first hole and the second hole are symmetrical to each other.

The display device includes a filler filled in the hole.

The filler is a conductive organic filler (e.g., an electrically conductive organic filler), a metal, or a combination thereof.

The first conductive bonding pattern and the second conductive bonding pattern each include a polymer resin and conductive nanoparticles (e.g., electrically conductive nanoparticles) dispersed in the polymer resin.

The conductive nanoparticles are conductive carbon black (e.g., electrically conductive carbon black).

The height of the first conductive bonding pattern and the height of the second conductive adhesive pattern are each 1 μm or less.

The display device further includes a reflective partition wall that surrounds the light emitting element in a plane, wherein the reflective partition wall includes, an organic layer defining a shape of the reflective partition wall and a reflective layer on the organic layer.

The top surface of the reflective partition wall is provided lower than a top surface of the light emitting element.

According to one or more embodiments of the present disclosure, an electronic device includes a display panel, a window on the display panel and a bottom cover below the display panel, wherein the display panel includes, a substrate, a pixel electrode and a common electrode spaced apart from each other on the substrate, a first organic layer covering at least a portion of the pixel electrode and the common electrode and a light emitting element on the first organic layer and including a conductive layer (e.g., an electrically conductive layer), a first semiconductor layer, an active layer, a second semiconductor layer, a first contact electrode, and a second contact electrode, wherein the light emitting element further includes, a plurality of holes that penetrate the conductive layer, the first semiconductor layer, and the active layer to expose the second semiconductor layer, wherein the first contact electrode is electrically connected to the conductive layer, and wherein the second contact electrode is electrically connected to the exposed second semiconductor layer.

According to the display device and the manufacturing method thereof according to the embodiments, the occurrence of air pockets that may be formed by the holes of a flip-type micro LED is prevented or reduced, thereby reducing or minimizing bonding defects of a light emitting element. Accordingly, the possibility of causing dark spots if (e.g., when) the display panel is turned on may be reduced, and the reliability of the panel may be improved.

However, the effects, aspects, and features of embodiments of the present disclosure are not limited to the aforementioned effects, aspects, and features, and various other suitable effects, aspects, and features are included in the present specification.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout diagram illustrating pixels of a display area according to one embodiment.

FIG. 6 is a cross-sectional view illustrating an example cross-section of one display panel corresponding to lines I-I' in FIG. 5.

FIG. 7 is a cross-sectional view illustrating an example of area A in FIG. 6 in more detail.

FIG. 8 is an enlarged view and a plan view of a plurality of holes of FIG. 7.

FIG. 9 is an enlarged view and a plan view of a plurality of holes of FIG. 7 according to another embodiment.

FIG. 10 is a photograph of a light emitting element having a single hole.

FIGS. 11 and 12 are enlarged views illustrating another example of the A area of FIG. 6 in more detail.

FIG. 13 is a cross-sectional view illustrating another example of the cross-section of the display panel corresponding to the line I-I’ of FIG. 5.

FIG. 14 is a cross-sectional view illustrating an embodiment of the B area of FIG. 13 in more detail.

FIG. 15 is a cross-sectional view illustrating an embodiment of the B area of FIG. 13 in more detail according to another embodiment.

FIGS. 16 and 17 are enlarged views illustrating another example of the B area of FIG. 13 in more detail.

FIGS. 18 and 19 are example drawings illustrating a smart watch including a display device according to one embodiment.

FIG. 20 is an exploded perspective view of a smart watch including a display device according to one embodiment.

FIGS. 21 is an example view of a virtual reality (VR) device including a display device according to one or more embodiments.

FIG. 22 is an example view of a VR device including a display device according to one or more embodiments.

FIG. 23 is an example view illustrating a vehicle instrument cluster and center fascia including display devices according to one or more embodiments.

FIG. 24 is an example view of a transparent display device including a display device according to one or more embodiments.

### DETAILED DESCRIPTION

Aspects and features of embodiments of the disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various suitable different forms, and should not be construed as being limited to only the illustrated embodiments herein. Rather, these embodiments are provided as examples so that the disclosure will be thorough and complete, and will fully convey the aspects and features of embodiments of the disclosure to those skilled in the art. Accordingly, processes, elements, and techniques that are not necessary to those having ordinary skill in the art for a complete understanding of the aspects and features of embodiments of the disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like, of the elements, unless specified.

Various suitable embodiments are described herein with reference to sectional illustrations that are schematic illustrations of embodiments and/or intermediate structures. As such, suitable variations from the shapes of the illustrations as a result, for example, of manufacturing techniques and/or tolerances, are to be expected. Further, specific structural or functional descriptions disclosed herein are merely illustrative for the purpose of describing embodiments according to the disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. As those skilled in the art would realize, the described embodiments may be modified in various suitable different ways, all without departing from the spirit and/or scope of the disclosure.

In the detailed description, for the purposes of explanation, numerous example details are set forth to provide a thorough understanding of various suitable embodiments. It is apparent, however, that various suitable embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, if (e.g., when) a first part is described as being “on” a second part, this indicates that the first part is provided at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that if (e.g., when) an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, if (e.g., when) a layer, region, or component is referred to as being "electrically connected" or "electrically coupled" to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. In embodiments, other expressions describing relationships between components such as “between,” “immediately between” or “adjacent to” and “directly adjacent to” may be construed similarly. In embodiments, it will also be understood that if (e.g., when) an element or layer is referred to as being “between” two elements or layers, it can be the only element or layer between the two elements or layers, or one or more intervening elements or layers may also be present.

For the purposes of the disclosure, expressions such as “at least one of,” “one of,” and “selected from,” if (e.g., when) preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any suitable variation thereof. Similarly, the expression such as "at least one of A and/or B" may include A, B, or A and B. As used herein, the term “and/or” includes any and all combinations of one or more of the associated listed items. For example, the expression such as "A and/or B" may include A, B, or A and B. Further, the use of “may” if (e.g., when) describing embodiments of the disclosure refers to “one or more embodiments of the disclosure".

It will be understood that, although the terms “first,” “second,” “third,” and/or the like, may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular (e.g., substantially perpendicular) to one another, or may represent different directions that are not perpendicular to one another. The same applies for first, second, and/or third directions.

The terminology used herein is for the purpose of describing particular embodiments only and is not intended to be limiting of the disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” if (e.g., when) used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations, or within ± 30%, 20%, 10%, 5% of the stated value. Further, the use of “may” if (e.g., when) describing embodiments of the disclosure refers to “one or more embodiments of the disclosure.”

If (e.g., when) one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the disclosure.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

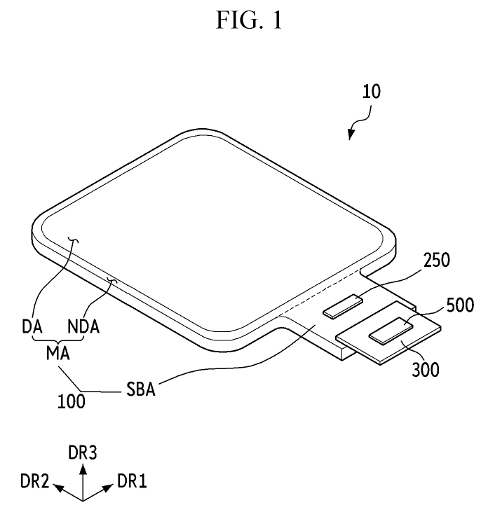

FIG. 1 is a schematic perspective view illustrating a display device according to an embodiment.

Referring to FIG. 1, a display device 10 may be to display video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of suitable products such as televisions, laptops, monitors, billboards, and the internet of things (IOT) devices.

The display device 10 may be a light emitting display device, such as an organic light-emitting display device that utilizes an organic light-emitting diode, a quantum dot light-emitting display device including a quantum dot light-emitting layer, an inorganic light-emitting display device including an inorganic semiconductor, and a miniaturized light-emitting display device that utilize a micro and/or nano light emitting diode (micro LED and/or nano LED). Hereinafter, the description focuses on the fact that the display device 10 is a micro-light emitting display device, but the disclosure is not limited thereto. Hereinafter, an ultra-small light emitting diode is described as a light emitting element for convenience of explanation.

The display device 10 may include a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a selected curvature or may be formed at a right angle. The planar shape of the display panel 100 is not limited to a rectangle, but may be formed in other polygonal, circular (e.g., generally circular), or oval (generally oval) shapes. The display panel 100 may be formed flat but is not limited thereto. For example, the display panel 100 may be formed at the left and right ends and may include curved portions having a constant curvature or a changing curvature. The display panel 100 may be flexibly formed to be bent, curved, bent, folded, and/or rolled.

The substrate SUB of the display panel 100 may include a main area MA and a sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits light of a first color, a second sub-pixel that emits light of a second color, and a third sub-pixel that emits light of a third color. However, the embodiments of the disclosure are not limited thereto.

The sub-area SBA may protrude from a side of the main area MA in the second direction DR2. Although FIG. 1 illustrates the sub-area SBA being unfolded, the sub-area SBA may be bent, and for example, may be on the lower surface of the display panel 100. In embodiments in which the sub-area SBA is bent, it may overlap the main area MA in the third direction DR3, which is the thickness direction of the display panel 100. The display driving circuit 250 may be provided in the sub-area SBA.

The display driving circuit 250 may generate signals and voltages to drive the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. The display driving circuit 250 may be attached to the circuit substrate 300 using a chip on film (COF) method.

The circuit substrate 300 may be attached to an end of the sub-area SBA of the display panel 100. For example, the circuit substrate 300 may be electrically connected to the display panel 100 and the display driving circuit 250. The display panel 100 and the display driving circuit 250 may receive digital video data, timing signals, and/or driving voltages through the circuit substrate 300. The circuit substrate 300 may be a flexible film, such as a flexible printed circuit substrate, a printed circuit substrate, and/or a chip on film.

The power supply circuit 500 may generate a plurality of panel driving voltages according to an external power supply voltage. The power supply circuit 500 may be formed as an integrated circuit (IC) and attached to the circuit substrate 300 using a COF method.

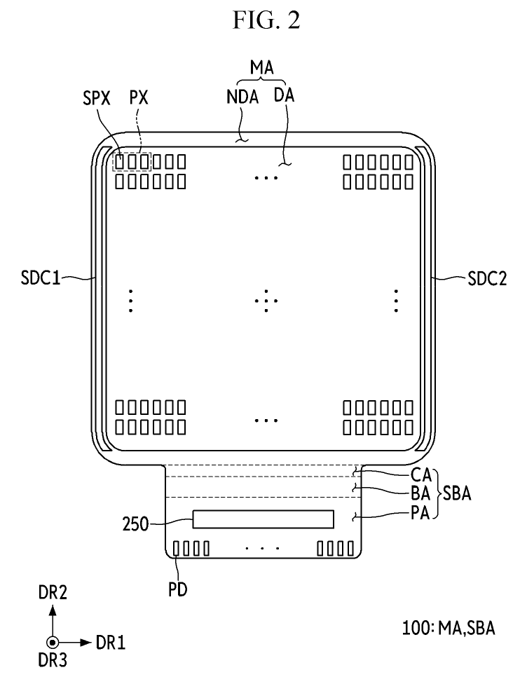

FIG. 2 is a schematic layout illustrating a display device according to an embodiment. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA, for example, a peripheral area of the display area DA. The display area DA may occupy most of the main area MA. The display area DA may be provided in the center of the main area MA.

The display area DA may include a plurality of pixels PX for that display an image, and each of the plurality of pixels PX may include a plurality of sub-pixels SPX. A pixel PX may be defined as a sub-pixel group of the smallest unit capable of expressing a white grayscale.

The non-display area NDA may be provided adjacent to the display area DA. The non-display area NDA may be an area provided outside the display area DA. The non-display area NDA may be provided to surround the display area DA. The non-display area NDA may be an edge area of the display panel 100.

A first scan driving portion SDCb and a second scan driving portion SDC2 may be provided in the non-display area NDA. The first scan driving portion SDC1 may be on a side (e.g., the left side) of the display panel 100, and the second scan driving portion SDC2 may be on another side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from a side of the main area MA in the second direction DR2. The length of the sub-area SBA in the second direction DR2 may be smaller than the length of the main area MA in the second direction DR2. The length of the first direction DR1 of the sub-area SBA may be less than the length of the first direction DR1 of the main area MA or may be substantially equal to the length of the first direction DR1 of the main area MA. The sub-area SBA may be curved and may be provided at a lower portion of the display panel 100. For example, the sub-area SBA may overlap the main area MA in the third direction DR3.

The sub-area SBA may include a connection area CA, a pad area PA, and a bending area BA.

The connection area CA may be an area that protrudes from a side of the main area MA in the second direction DR2. A side of the connection area CA may be in contact with the non-display area NDA of the main area MA, and another side of the connection area CA may be in contact with the bending area BA.

The pad area PA may be an area where the pads PD and the display driving circuit 250 may be provided. The display driving circuit 250 may be attached to the driving pads of the pad area PA using a conductive adhesive member (e.g., an electrically conductive adhesive member) such as an anisotropic conductive film. The circuit substrate 300 may be attached to the pads PD of the pad area PA using a conductive adhesive member (e.g., an electrically conductive adhesive member) such as an anisotropic conductive film. A side of the pad area PA may be in contact with the bending area BA.

The bending area BA may be a bent area. In embodiments in which the bending area BA is bent, the pad area PA may be provided below the connection area CA and below the main area MA. The bending area BA may be between the connection area CA and the pad area PA. A side of the bending area BA may be in contact with the connection area CA, and another side of the bending area BA may be in contact with the pad area PA.

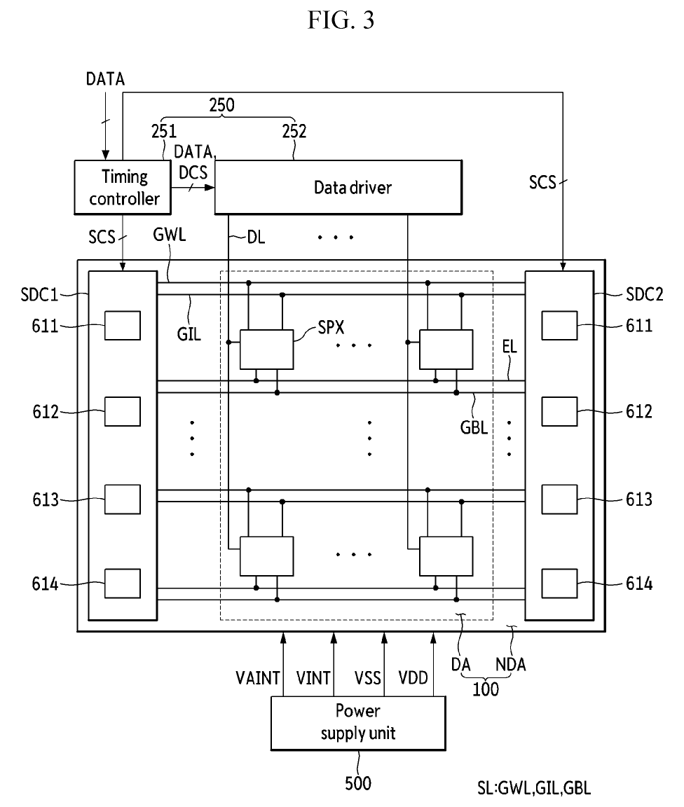

FIG. 3 is a schematic block diagram illustrating a display device according to an embodiment.

Referring to FIG. 3, the display area DA may include a plurality of pixels PX, a plurality of scan lines SL, a plurality of emission control lines EL, and a plurality of data lines DL.

The plurality of pixels PX may be provided in a matrix form in the first direction DR1 and the second direction DR2. The plurality of scan lines SL and the plurality of emission control lines EL may extend in the first direction DR1 and be provided in the second direction DR2. The plurality of data lines DL may extend in the second direction DR2 and be provided in the first direction DR1. The plurality of scan lines SL may include a plurality of write scan lines GWL, a plurality of initialization scan lines GIL, and a plurality of bias scan lines GBL.

Each of the plurality of sub-pixels SPX may be electrically connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light emitting elements according to the data voltage.

The non-display area NDA may include a first scan driving portion SDC1, a second scan driving portion SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 may include a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. For example, the sub-pixels SPX may be selected by the write scan signals of the first scan driving portion SDC1 and the second scan driving portion SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit 500 may generate a plurality of panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

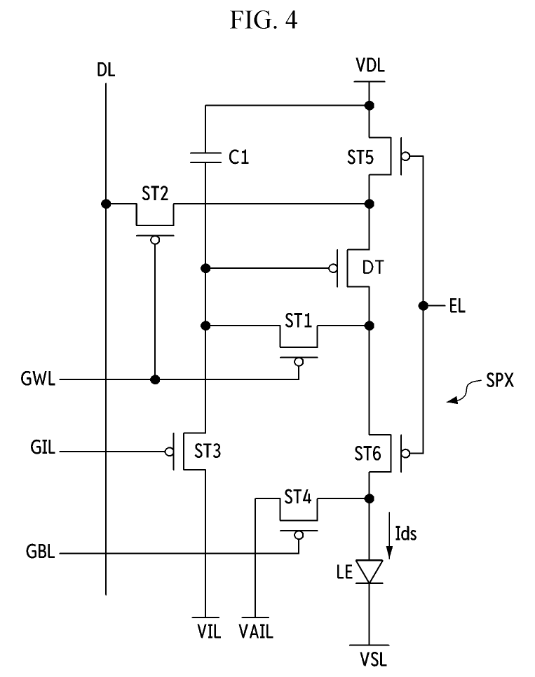

FIG. 4 is a schematic diagram of an equivalent circuit of a sub-pixel according to an embodiment.

Referring to FIG. 4, a sub-pixel SPX according to an embodiment may be electrically connected to scan lines GWL, GIL, and GBL, an emission control line EL, and a data line DL. For example, the sub-pixel SPX may be electrically connected to a write scan line GWL, an initialization scan line GIL, a bias scan line GBL, an emission control line EL, and a data line DL.

The sub-pixel SPX according to an embodiment may include a driving transistor DT, switching elements, a capacitor, and a light emitting element LE. The switching elements include first to sixth transistors ST1, ST2, ST3, ST4, ST5, and ST6.

The driving transistor DT may include a gate electrode, a first electrode, and a second electrode. The driving transistor DT controls a drain-source current (Ids, hereinafter referred to as "driving current") the flows between the first electrode and the second electrode according to a data voltage applied to a gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE may be electrically connected to the first electrode of the fourth transistor ST4 and the second electrode of the sixth transistor ST6, and the cathode electrode may be electrically connected to a second power supply line VSL to which a second power supply voltage is applied.

A capacitor C1 may be formed between a gate electrode of a driving transistor DT and a first power supply line VDL to which a first power supply voltage is applied. The first power supply voltage may be a voltage of a higher level than the second power supply voltage. An electrode of the capacitor C1 may be electrically connected to the gate electrode of the driving transistor DT, and another electrode may be electrically connected to the first power supply line VDL.

As shown in FIG. 4, the first to sixth transistors ST1, ST2, ST3, ST4, ST5, and ST6 and the driving transistor DT may all be formed as p-type MOSFET. For example, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 may be formed as p-type MOSFET and they may be turned on in embodiments in which a scan signal of a gate low voltage and an emission control signal are applied to the initialization scan line GIL, the write scan line GWL, the bias scan line GBL, and the emission control line EL, respectively. An electrode of the third transistor ST3 may be connected to a first initialization voltage line VIL to which the third power supply voltage (VINT of FIG. 3) is applied, and an electrode of the fourth transistor ST4 may be connected to a second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

In another embodiment, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. For example, the active layers of each of the driving transistor DT, the second transistor ST2, the fourth transistor ST4, the fifth transistor ST5, and the sixth transistor ST6 formed of p-type MOSFETs may be formed of polysilicon, the active layers of each of the first transistor ST1 and the third transistor ST3 formed of an n-type MOSFET may be formed of an oxide semiconductor. Furthermore, because the first transistor ST1 and the third transistor ST3 may be formed as n-type MOSFET, the first transistor ST1 may be turned on in embodiments in which a scan signal of the gate high voltage is applied, and the third transistor ST3 may be turned on if (e.g., when) an initialization scan signal of the gate high voltage is applied. In embodiments, the second transistor ST2, the fourth transistor ST4, the fifth transistor ST5, and the sixth transistor ST6 may be formed as p-type MOSFET so that they may be turned on in embodiments in which a scan signal of the gate low voltage and a light emission control signal are applied.

In another embodiment, the fourth transistor ST4 may be formed as an n-type MOSFET, and the remaining transistors DT, ST1, ST2, ST3, ST5, and ST6 may be formed as p-type MOSFET, in which embodiments the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on in embodiments in which a scan signal of a gate high voltage is applied, whereas the remaining transistors DT, ST1, ST2, ST3, ST5, and ST6 may be turned on in embodiments in which a scan signal of a gate low voltage and a light emission control signal are applied.

In another embodiment, the first to sixth transistors ST1, ST2, ST3, ST4, ST5, and ST6 and the driving transistor DT may all be formed as n-type MOSFET. For example, the active layer of each of the first to sixth transistors ST1, ST2, ST3, ST4, ST5, and ST6 and the driving transistor DT may be formed of an oxide semiconductor and may be turned on in embodiments in which a scan signal of a gate high voltage and a light emission control signal are applied.

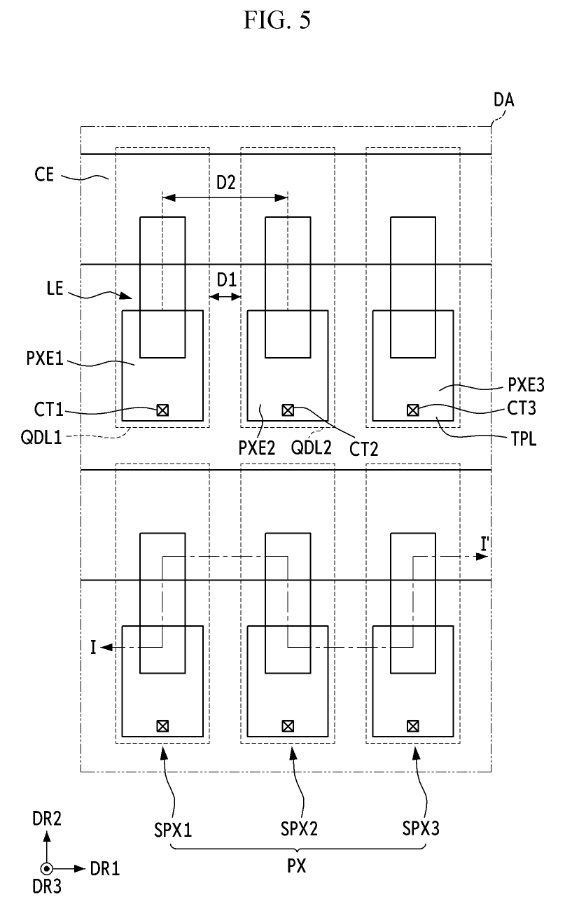

FIG. 5 is a layout diagram illustrating pixels of a display area according to one embodiment.

Referring to FIG. 5, each of the plurality of pixels PX of the display area DA may include three sub-pixels SPX1, SPX2, and SPX3, but the embodiment of the present disclosure is not limited thereto and may include four sub-pixels. If (e.g., when) each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be provided in a matrix form. In each of the plurality of pixels PX, the first sub-pixel SPX1, the second sub-pixel SPX2, and the third sub-pixel SPX3 may be provided in a first direction DR1.

If (e.g., when) each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. In embodiments, the light of the first color may be light in a red wavelength band, the light of the second color may be light in a green wavelength band, and the light of the third color may be light in a blue wavelength band. For example, the blue wavelength band may refer to the light having a main peak wavelength in a wavelength band from approximately 370 μm to 460 μm, the green wavelength band may refer to the light having a main peak wavelength in a wavelength band from approximately 480 μm to 560 μm, and the red wavelength band may refer to the light having a main peak wavelength in a wavelength band from approximately 600 μm to 750 μm.

In embodiments, if (e.g., when) each of the plurality of pixels PX includes four sub-pixels, the first sub-pixel may emit light of a first color, the second and fourth sub-pixels may emit light of a second color, and the third sub-pixel may emit light of a third color. In embodiments, the first sub-pixel may emit light of a first color, the second sub-pixel may emit light of a second color, the third sub-pixel may emit light of a third color, and the fourth sub-pixel may emit light of a fourth color. In embodiments, the fourth color light may be white light.

The first sub-pixel SPX1 includes a first pixel electrode PXE1, a common electrode CE, a light emitting element LE, and a first light conversion layer QDL1. The second sub-pixel SPX2 includes a second pixel electrode PXE2, a common electrode CE, a light emitting element LE, and a second light conversion layer QDL2. The third sub-pixel SPX3 includes a third pixel electrode PXE3, a common electrode CE, a light emitting element LE, and a light transmission layer TPL.

In each of the first sub-pixel SPX1, the second sub-pixel SPX2, and the third sub-pixel SPX3, the pixel electrodes PXE1, PXE2, and PXE3 and the common electrode CE may be provided in the second direction DR2. Each of the pixel electrodes PXE1, PXE2, and PXE3 may have a rectangular planar shape, but the embodiments of the present disclosure are not limited thereto.

In the embodiment of FIG. 5, an area of the first pixel electrode PXE1, an area of the second pixel electrode PXE2, and an area of the third pixel electrode PXE3 may be the same but are not limited thereto.

For example, if (e.g., when) the light conversion efficiency of the second light conversion layer QDL2 is lower than the light conversion efficiency of the first light conversion layer QDL1, the area of the second pixel electrode PXE2 may be larger than the area of the first pixel electrode PXE1. In embodiments, because the light transmission layer TPL directly transmits the light of the light emitting element LE, while the first light conversion layer QDL1 must convert the light, the area of the first pixel electrode PXE1 may be larger than the area of the third pixel electrode PXE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The common electrode CE may be connected to a second power supply line VSL to which a second driving voltage VSS is applied through a common connection hole. Thus, the second driving voltage VSS may be applied to the common electrodes CE. The pixel electrodes PXE1, PXE2, and PXE3 may be referred to as an anode electrode or a first electrode, and the common electrode CE may be referred to as a cathode electrode or a second electrode.

A plurality of light emitting elements LE may be on the pixel electrodes PXE1, PXE2, and PXE3 and the common electrode CE. Each of the plurality of light emitting elements LE may have a rectangular planar shape, but the embodiment of the present disclosure is not limited thereto. For example, each of the plurality of light emitting elements LE may have a circular (e.g., substantially circular) planar shape.

The first light conversion layer QDL1 may completely overlap the plurality of light emitting elements LE of the first sub-pixel SPX1. The first light conversion layer QDL1 may convert or shift the peak wavelength of incident light into light of another set or specific peak wavelength and emit the light. For example, the first light conversion layer QDL1 may convert or shift the third light emitted from the plurality of light emitting elements LE of the first sub-pixel SPX1 into the first light.

The second light conversion layer QDL2 may completely overlap the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another set or specific peak wavelength and emit the light. For example, the second light conversion layer QDL2 may convert or shift the third light emitted from the plurality of light emitting elements LE of the second sub-pixel SPX2 into the second light.

The light transmission layer TPL may completely overlap with the plurality of light emitting elements LE of the third sub-pixel SPX3. The light transmission layer TPL may directly transmit incident light. For example, the light transmission layer TPL may directly transmit third light emitted from the plurality of light emitting elements LE of the third sub-pixel SPX3.

If (e.g., when) the light emitting elements LE of the first sub-pixel SPX1 emit light of a first color, the light emitting elements LE of the second sub-pixel SPX2 emit light of a second color, and the light emitting elements LE of the third sub-pixel SPX3 emit light of a third color, the light conversion layers QDL1 and QDL2 and the light transmission layer TPL may be omitted.

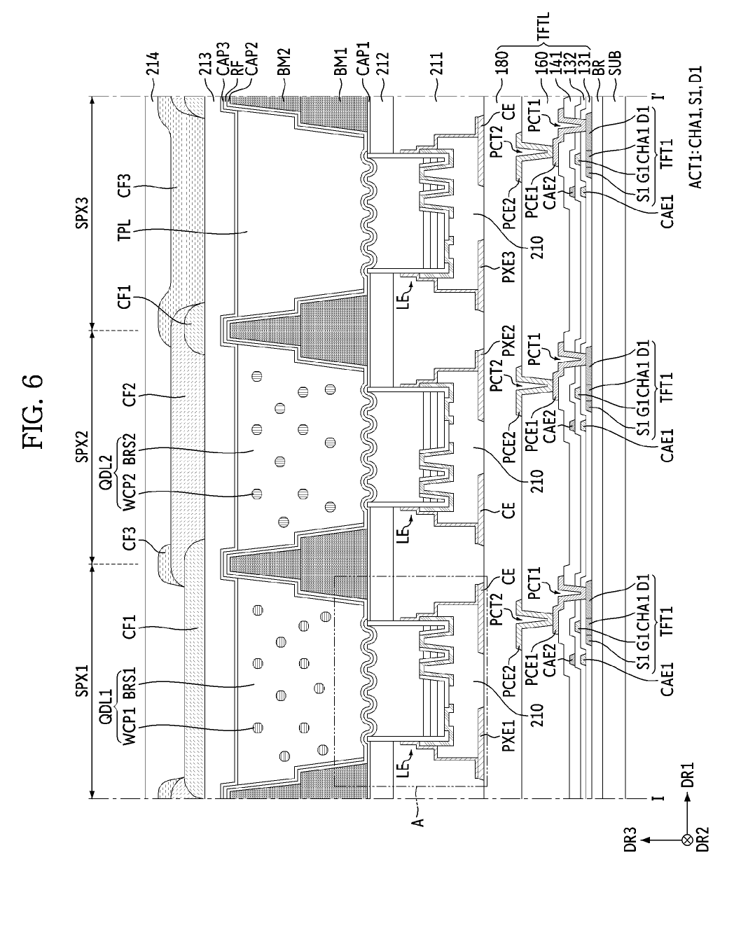

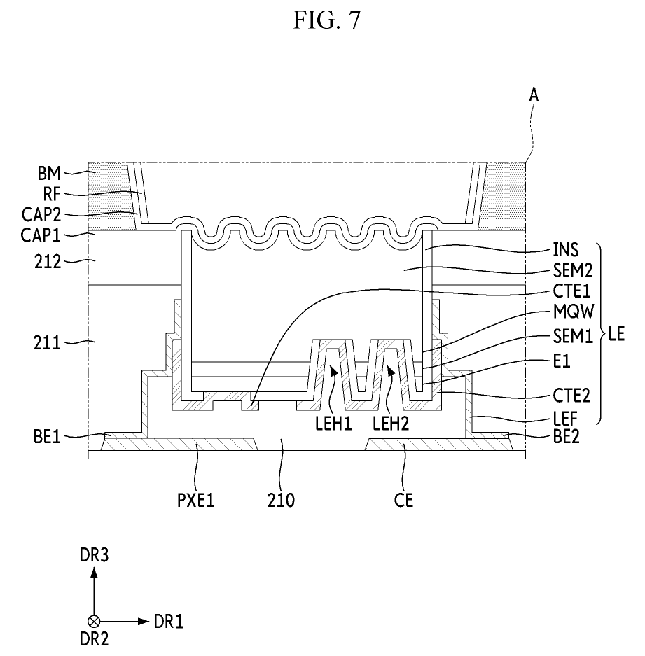

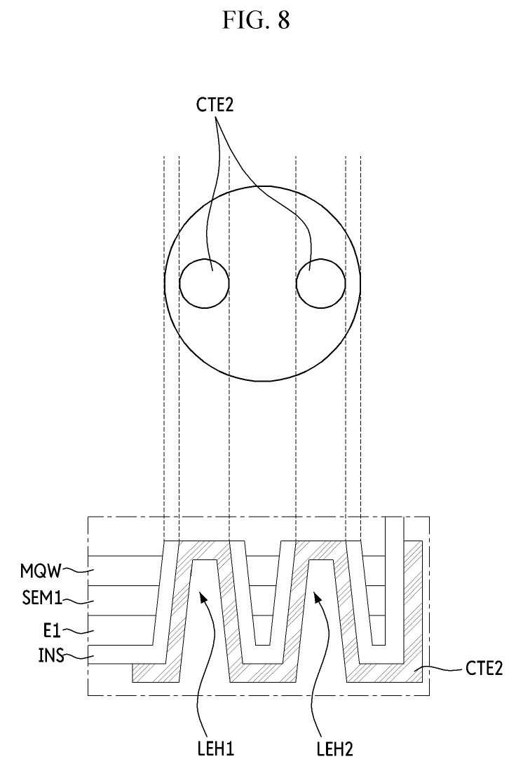

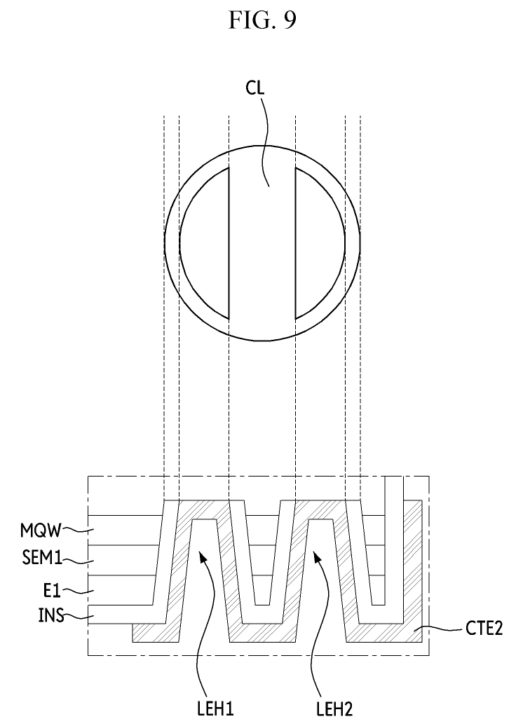

FIG. 6 is a cross-sectional view illustrating an example cross-section of one display panel corresponding to lines I-I' in FIG. 5. FIG. 7 is a cross-sectional view illustrating an example of area A in FIG. 6 in detail. FIG. 8 is an enlarged view and a plan view of a plurality of holes of FIG. 7. FIG. 9 is an enlarged view and a plan view of a plurality of holes of FIG. 7 according to another embodiment.

Referring to FIGS. 6-7, a substrate SUB may be made of an insulating material (e.g., an electrically insulating material) such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be on the substrate SUB. The barrier film BR is a film that protects the thin-film transistors TFT1 of the thin-film transistor layer TFTL from moisture that would otherwise penetrate through the substrate SUB which is vulnerable to moisture permeation. The barrier film BR may be formed of a plurality of inorganic films that are alternately stacked.

A thin-film transistor TFT1 may be on the barrier film BR. The thin-film transistor TFT1 may be either the fourth transistor ST4 or the sixth transistor ST6 shown in FIG. 4. The thin-film transistor TFT1 may include a first active layer ACT1 and a first gate electrode G1.

The first active layer ACT1 of the thin-film transistor TFT1 may be on the barrier film BR. The first active layer ACT1 of the thin-film transistor TFT1 may include polycrystalline silicon, monocrystalline silicon, low-temperature polycrystalline silicon, or amorphous silicon. In embodiments, the first active layer ACT1 of the thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area that overlaps the first gate electrode G1 in the third direction DR3, which is the thickness direction of the substrate SUB. The first source area S1 may be on one side of the first channel area CHA1, and the first drain area D1 may be on the other side of the first channel area CHA1. The first source area S1 and the first drain area D1 may be areas that do not overlap with the first gate electrode G1 in the third direction DR3. The first source area S1 and the first drain area D1 may be conductive areas (e.g., electrically conductive areas) in which semiconductor materials are doped with ions.

A first gate insulating film 131 may be on the first channel area CHA1, the first source area S1, and the first drain area D1 of the thin-film transistor TFT1.

A first gate metal layer may be on the first gate insulating film 131. The first gate metal layer may include a first gate electrode G1 of a thin-film transistor TFTb and a first capacitor electrode CAE1. The first gate electrode G1 may overlap the first active layer ACT1 in the third direction DR3. Although the first gate electrode G1 and the first capacitor electrode CAE1 are illustrated as being spaced apart from each other in FIG. 6, the first gate electrode G1 and the first capacitor electrode CAE1 may be connected to each other.

A second gate insulating film 132 may be on the first gate electrode G1 and the first capacitor electrode CAE1 of the thin-film transistor TFT1.

A second gate metal layer may be on the second gate insulating film 132. The second gate metal layer may include a second capacitor electrode CAE2. The second capacitor electrode CAE2 may overlap the first capacitor electrode CAE1 of the thin-film transistor TFT1 in the third direction DR3. Because the second gate insulating film 132 has a set or predetermined dielectric constant, the capacitor (C1 in FIG. 4) may be formed by the first capacitor electrode CAE1, the second capacitor electrode CAE2, and the second gate insulating film 132 provided between them.

A first interlayer insulating film 141 may be on the second capacitor electrode CAE2.

A first data metal layer may be on the first interlayer insulating film 141. The first data metal layer may include a first source connection electrode PCE1. The first source connection electrode PCE1 may be connected to the first drain area D1 of the first active layer ACT1 through a first source contact hole PCT1 that penetrates the first gate insulating film 131, the second gate insulating film 132, and the interlayer insulating film 141.

A first planarization organic film 160 may be on the first source connection electrode PCE1 to planarize a step caused by the thin-film transistor TFT1.

A second data metal layer may be on the first planarization organic film 160. The second data metal layer may include a second source connection electrode PCE2. The second source connection electrode PCE2 may be connected to the first source connection electrode PCE1 through a second pixel contact hole (PCT2) that penetrates the first planarization organic film 160.

A second planarization organic film 180 may be on the second source connection electrode PCE2.

The barrier film BR, the first gate insulating film 131, the second gate insulating film 132, the third gate insulating film 133, and the interlayer insulating film 141 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or a plurality of layers of any one of molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be on the second planarization organic film 180. The light emitting element layer may include pixel electrodes PXE1, PXE2, and PXE3, light emitting elements LE, a common electrode CE, and a first organic layer 210.

The pixel electrode layer including pixel electrodes PXE1, PXE2, and PXE3 and the common electrode CE may be on the second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) that penetrates the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrode CE may be connected to a second power supply line (VSL in FIG. 4) to which a second driving voltage (VSS in FIG. 3) is applied through a common connection hole. Thus, the second driving voltage VSS may be applied to the common electrode CE.

The pixel electrode layer may be formed as a single layer or a plurality of layers of any one of molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) having low surface resistance (e.g., electrical surface resistance) to lower the resistance (e.g., electrical resistance) of each of the pixel electrodes PXE1, PXE2, and PXE3.

The first organic layer 210 may be on each of the pixel electrode layers. For example, the first organic layer 210 may cover at least a portion of the pixel electrodes PXE1, PXE2, and PXE3 and at least a portion of the common electrodes CE1, CE2, and CE3.

The first organic layer 210 temporarily fixes or adheres an upper member (e.g., a light emitting element LE). For example, the first organic layer 210 may be a film for pseudo-adhesion of an upper member (e.g., a light emitting element LE) onto each of the pixel electrodes PXE1, PXE2, and PXE3 and the common electrode CE. To facilitate the pseudo-adhesion, the thickness of the first organic layer 210 may be greater than the thickness of each of the pixel electrodes PXE1, PXE2, and PXE3 and the common electrode CE and may be greater than the thickness of the contact electrodes CTE1 and CTE2. The thickness of the first organic layer 210 may be about 2 µm but is not limited thereto.

The first organic layer 210 may be a photosensitive organic film such as a photoresist. In embodiments, the first organic layer 210 may be formed from an acrylic resin, an epoxy resin, a phenolic resin, a polyamide resin, a polyimide resin, and/or the like.

The plurality of light emitting elements LE may be on the first organic layer 210. In FIGS. 6 and 7, the light emitting element LE is illustrated as a flip-type micro LED. The flip-type micro LED refers to an LED in which contact electrodes CTE1 and CTE2 are formed on one surface (e.g., the bottom surface) of the light emitting element LE.

The light emitting element LE may have various suitable shapes, such as a shape of a rod, wire, tube, and/or the like, a shape of a polygonal column such as a regular hexahedron, a rectangular parallelepiped, a hexagonal column, and/or the like, or a shape that extends in one direction but has a partially sloped outer surface.

Each of the plurality of light emitting elements LE may be formed from an inorganic material such as gallium nitride (GaN).

Each of the plurality of light emitting elements LE may be formed by growing on a semiconductor substrate such as a silicon substrate or a sapphire substrate. The plurality of light emitting elements LE may be transferred onto the pixel electrode layer of the display panel 100 directly from the semiconductor substrate or through a relay substrate. In embodiments, the plurality of light emitting elements LE may be transferred onto the pixel electrodes PXE1, PXE2, and PXE3 of the display panel 100 by an electrostatic method using an electrostatic head and/or a stamp method using an elastic polymer material such as PDMS (Polydimethylsiloane) and/or silicon as a transfer substrate.

Each of the plurality of light emitting elements LE may include a conductive layer E1, a first semiconductor layer SEM1, an active layer MQW, a second semiconductor layer SEM2, a protective layer INS, a first contact electrode CTE1, and a second contact electrode CTE2.

The conductive layer E1 may be on the bottom surface of the first semiconductor layer SEM1. In FIG. 7, the conductive layer E1 is illustrated as covering the entire bottom surface of the first semiconductor layer SEMb, but the embodiment of the present disclosure is not limited thereto. For example, the conductive layer E1 may be on a portion of the bottom surface of the first semiconductor layer SEM1. The conductive layer E1 may include one selected from molybdenum (Mo), aluminum (Al), chromium (Cr), gold (Au), titanium (Ti), nickel (Ni), neodymium (Nd), and copper (Cu).

The first semiconductor layer SEM1 may be on the conductive layer E1. The first semiconductor layer SEM1 may be formed of a semiconductor material layer doped with a first conductive dopant (e.g., a first electrically conductive dopant) such as magnesium (Mg), zinc (Zn), calcium (Ca), strontium (Sr), barium (Ba), and/or the like, for example, gallium nitride (GaN).

The active layer MQW may be on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. If (e.g., when) the active layer MQW includes a material having a multi-quantum well structure, it may have a structure in which a plurality of well layers and barrier layers are alternately stacked. In embodiments, the well layer may be formed of indium gallium nitride (InGaN), and the barrier layer may be formed of gallium nitride (GaN) and/or aluminum gallium nitride (AlGaN), but embodiments of the present disclosure are not limited thereto.

In embodiments, the active layer MQW may have a structure in which semiconductor materials having a high band gap energy and semiconductor materials having a low band gap energy are alternately stacked with each other, may include other Group three to five semiconductor materials according to the wavelength range of emitted light.

In one embodiment, if (e.g., when) the active layer MQW includes InGaN, the color of the emitted light may suitably vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be approximately 10 wt% to 20 wt%.

The second semiconductor layer SEM2 may be on the first semiconductor layer SEM1. The second semiconductor layer SEM2 may be a semiconductor material layer doped with a second conductivity type dopant such as silicon (Si), germanium (Ge), tin (Sn), and/or the like, for example, gallium nitride (GaN).

An electron blocking layer may be between the first semiconductor layer SEM1 and the active layer MQW. The electron blocking layer may be a layer to suppress or prevent too many electrons from flowing into the active layer MQW (or to reduce a flow of electrons into the active layer MQW). For example, the electron blocking layer may be aluminum gallium nitride (AlGaN) and/or p-type aluminum gallium nitride (AlGaN) doped with p-type magnesium (Mg). The electronic blocking layer may be omitted.

A superlattice layer may be between the active layer MQW and the second semiconductor layer SEM2. The superlattice layer may be a layer that relieves stress between the second semiconductor layer SEM2 and the active layer MQW. For example, the superlattice layer may be aluminum gallium nitride (AlGaN) and/or p-type aluminum gallium nitride (AlGaN) doped with p-type magnesium (Mg). The superlattice layer may be omitted.

The protective film INS may be a film that protects the bottom surface and the side surface of the light emitting element LE. The protective film INS may be on the bottom surface and the side surface of the conductive layer E1 and the side surface of the semiconductor layer SEM1, MQW, and SEM2. For example, the protective film INS may be on the bottom surface and the side surface of the conductive layer E1, the side surface of the first semiconductor layer SEM1, the side surface of the active layer MQW, and the side surface of the second semiconductor layer SEM2.

The protective film INS may be formed from an inorganic film, such as silicon nitride (SiNₓ), silicon oxide nitride (SiON), silicon oxide (SiOₓ), titanium oxide (TiOₓ), and/or aluminum oxide (AlOₓ). The protective film INS is, for example, provided from one end to the other end of the side surface of the light emitting element LE but may be provided slightly apart from one end due to process tolerances.

Referring to FIGS. 7 and 8, a plurality of holes LEH1 and LEH2 may be formed to penetrate a conductive layer E1, a first semiconductor layer SEM1, and an active layer MQW of a light emitting element LE and expose a second semiconductor layer SEM2. The plurality of holes LEH1 and LEH2 may include a first hole LEH1 and a second hole LEH2. The first hole LEH1 and the second hole LEH2 may be symmetrical to each other and may have the same shape and the same size. Each of the first hole LEH1 and the second hole LEH2 may be circular (e.g., generally circular) in a plane and may be provided symmetrically to each other. The first hole LEH1 and the second hole LEH2 may be formed as a single layer, but is not limited thereto, and may have a multilayer structure. A set or certain thickness difference may exist between the layers of the multilayer structure. For example, as the holes LEH1 and LEH2 become deeper, e.g., toward the inner side of the hole, a width W-LEH of the holes LEH1, LEH2 may narrow, e.g., the inner wall surface may have a slope. The first hole LEH1 and the second hole LEH2 may have a trapezoidal shape in cross section. However, the embodiment is not limited thereto, and the width of the holes LEH1 and LEH2 may have a constant (e.g., substantially constant) rectangular shape.

Each of the first hole LEH1 and the second hole LEH2 may have a circular (e.g., substantially circular) planar shape as shown in FIG. 8, but the embodiment of the present disclosure is not limited thereto.

In another embodiment, as shown in FIG. 9, each of the first hole LEH1 and the second hole LEH2 may have a semicircular shape in a plane and may be provided symmetrically based on the center line CL of one circle. The radius of curvature of each of the first hole LEH1 and the second hole LEH2 may be a portion of a circle (e.g., substantially a circle). Further, the plurality of holes LEH1 and LEH2 may have a planar shape of a polygon, such as an ellipse or a square (e.g., substantially an ellipse or substantially a square).

Referring again to FIGS. 6-8, the protective film INS may be on the sidewall of the conductive layer E1 exposed by the plurality of holes LEH1 and LEH2, the sidewall of the first semiconductor layer SEM1, and the sidewall of the active layer MQW. The protective film INS may not cover the second semiconductor layer SEM2 in the plurality of holes LEH1 and LEH2. Thus, the second semiconductor layer SEM2 exposed by the plurality of holes LEH1 and LEH2 may be exposed without being covered by the protective film INS.

The first contact electrode CTE1 may be on at least one side surface and the bottom surface of the light emitting element LE. The first contact electrode CTE1 may be on the bottom surface of the conductive layer E1 that is not covered by the protective film INS. Thus, the first contact electrode CTE1 may be electrically connected to the conductive layer E1.

The second contact electrode CTE2 may be on at least one side surface and the bottom surface of the light emitting element LE. In embodiments, the first contact electrode CTE1 may be on the first side surface of the light emitting element LE and the first side surface of the conductive layer E1, while the second contact electrode CTE2 may be on the second side surface of the light emitting element LE and the second side surface of the conductive layer E1.

The second contact electrode CTE2 may on the protective film INS provided in the plurality of holes LEH1 and LEH2 and the second semiconductor layer SEM2 that is exposed in the plurality of holes LEH1 and LEH2 and is not covered by the protective film INS. Thus, the second contact electrode CTE2 may be electrically connected to the second semiconductor layer SEM2 through the plurality of holes LEH1 and LEH2.

As described above, the first contact electrode CTE1 and the second contact electrode CTE2 may be on at least a portion of the side surface of the light emitting element LE while being spaced apart from each other. For example, an area adjacent to the top surface of the light emitting element LE may be covered by the protective film INS but may be exposed without being covered by the first contact electrode CTE1 or the second contact electrode CTE2.

Each of the first contact electrode CTE1 and the second contact electrode CTE2 may be on three side surfaces of the light emitting element LE. For example, if (e.g., when) the light emitting element LE includes first to fourth sides, the first contact electrode CTE1 may be on the first side, the second side, and the third side, and the second contact electrode CTE2 may be on the second side, the third side, and the fourth side.

The first contact electrode CTE1 and the second contact electrode CTE2 may include one selected from molybdenum (Mo), aluminum (Al), chromium (Cr), gold (Au), titanium (Ti), nickel (Ni), neodymium (Nd), and copper (Cu). For example, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be between the first organic layer 210 and the protective film INS. The first organic layer 210 may be on a portion of the bottom surface and side surface of the first contact electrode CTE1 of eachof the light emitting elements LE and a portion of the bottom surface and side surface of the second contact electrode CTE2. In embodiments, the first organic layer 210 may be on the side surfaces of the conductive layer E1 of each of the light emitting elements LE. In embodiments, the first organic layer 210 may be on the side surfaces of the first semiconductor layer SEM1, the side surfaces of the active layer MQW, and the side surfaces of the second semiconductor layer SEM2 of each of the light emitting elements LE. In embodiments, the first organic layer 210 may be on a portion of each of the side surfaces of the second semiconductor layer SEM2.

The first connection electrode BE1 connects the first contact electrode CTE1 of the light emitting element LE and the pixel electrode PXE1, PXE2, and PXE3. The first connection electrode BE1 may be on the top surface of the pixel electrode PXE1, PXEb, and PXE3 that is not covered by the first organic layer 210 and may extend along the side surface and the top surface of the first organic layer 210. Also, the first connection electrode BE1 may be on the top surface of the first organic layer 210 and the first contact electrode CTE1.

The second connection electrode BE2 connects the second contact electrode CTE2 of the light emitting element LE and the common electrode CE. The second connection electrode BE2 may be on the top surface of the common electrode CE that is not covered by the first organic layer 210 and may extend along the side surface and the top surface of the second connection electrode BE2. In embodiments, the second connection electrode BE2 may be on the top surface of the first organic layer 210 and the second contact electrode CTE2.

In embodiments, an area adjacent to the top surface of the light emitting element LE on each of the side surfaces of the light emitting element LE may be exposed without being covered by the first connection electrode BE1 or the second connection electrode BE2.

The first connection electrode BE1 and the second connection electrode BE2 may cover the first contact electrode CTE1 and the second contact electrode CTE2 on each of the side surfaces of the light emitting element LE. For example, the separation distance between the first connection electrode BE1 or the second connection electrode BE2 on the top surface of the light emitting element LE may be smaller than the separation distance between the first contact electrode CTE1 or the second contact electrode CTE2. In embodiments, the first connection electrode BE1 may cover at least a portion of the protective film INS that is exposed and not covered by the first contact electrode CTE1. In embodiments, the first connection electrode BE1 may cover the entirety of the protective film INS that is exposed and not covered by the first contact electrode CTE1. As another example, the separation distance between the top surface of the semiconductor stack STC and the first connection electrode BE1 in the third direction DR3 may be substantially the same as the separation distance between the top surface of the light emitting element LE and the first contact electrode CTE1 in the third direction DR3.

In embodiments, the separation distance between the first connection electrode BE1 or the second connection electrode BE2 on the top surface of the light emitting element LE may be greater than the separation distance between the first contact electrode CTE1 or the second contact electrode CTE2, but the embodiment of the present disclosure is not limited thereto.

The first connection electrode BE1 and the second connection electrode BE2 may include one selected from molybdenum (Mo), aluminum (Al), chromium (Cr), gold (Au), titanium (Ti), nickel (Ni), neodymium (Nd), and copper (Cu). In embodiments, the first connection electrode BE1 and the second connection electrode BE2 may be made of a transparent conductive material (TCO), such as indium tin oxide (ITO) and indium zinc oxide (IZO).

A second organic layer 211 may cover a portion of the side surfaces of the plurality of light emitting elements LE. Further, the second organic layer 211 may cover the connection electrodes BE1 and BE2.

The third organic layer 212 may be on the second organic layer 211. The third organic layer 212 may cover another portion of the side surfaces of each of the plurality of light emitting elements LE. The third organic layer 212 may be on the protective film INS and the connection electrodes BE1 and BE2 that are not covered by the second organic layer 211 as shown in FIG. 7, but the embodiment of the present disclosure is not limited thereto. In one example, the entire connection electrodes BE1 and BE2 may be covered by the second organic layer 211. The upper surfaces of each of the plurality of light emitting elements LE may be exposed without being covered by the third organic layer 212.

The second organic layer 211 and the third organic layer 212 are layers that flatten the steps caused by the plurality of light emitting elements LE. If the height of the second organic layer 211 covers most of the side surfaces of each of the plurality of light emitting elements LE, the third organic layer 212 may be omitted.

The second organic layer 211 and the third organic layer 212 may be formed of an organic film such as an acrylic resin, an epoxy resin, a phenolic resin, a polyamide resin, a polyimide resin, and/or the like.

The first capping layer CAP1 may be on the third organic layer 212 and the light emitting element LE.

A light blocking layer BM, a first light conversion layer QDL1, a second light conversion layer QDL2, and a light transmission layer TPL may be on the first capping layer CAP1. The first light conversion layer QDL1, the second light conversion layer QDL2, and the light transmission layer TPL may be formed by the partition of the light blocking layer BM. Thus, the first light conversion layer QDL1 may be on the first capping layer CAP1 in the first sub-pixel SPX1, the second light conversion layer QDL2 may be on the first capping layer CAP1 in the second sub-pixel SPX2, and the light transmission layer TPL may be on the first capping layer CAP1 in the third sub-pixel SPX3. The light blocking layer BM may not overlap the plurality of light emitting elements LE in the third direction DR3.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially laminated. A length of the first light blocking layer BM1 in the first direction DR1 or a length of the second direction DR2 may be wider than a length of the second light blocking layer BM2 in the first direction DR1 or a length of the second light blocking layer BM2 in the second direction DR2. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light-blocking material to prevent light from a light emitting element LE of a sub-pixel from propagating to an adjacent sub-pixel. For example, the first light blocking layer BM1 and the second light blocking layer BM2 may include an inorganic black pigment such as carbon black and/or an organic black pigment.

The second capping layer CAP2 may be on the first capping layer CAP1 and the light blocking layer BM. The second capping layer CAP2 may be on the side surface and the top surface of the light blocking layer BM. For example, the second capping layer CAP2 may be on the side surface of the first light blocking layer BM1 and the side surface and the top surface of the second first light blocking layer BM2.

The reflective film RF may be between the light blocking layer BM and the first light conversion layer QDL1, between the light blocking layer BM and the second light conversion layer QDL2, and between the light blocking layer BM and the light transmission layer TPL. The reflective film RF may be on the second capping layer CAP2 on the side of the first light blocking layer BM1 and the side of the second light blocking layer BM2. The reflective film RF serves to reflect light that travels in the side direction in the first light conversion layer QDL1, the second light conversion layer QDL2, and the light transmission layer TPL.

The reflective film RF may include a metal material having a high reflectivity, such as aluminum (Al). The thickness of the reflective film RF may be approximately 0.1 μm.

In embodiments, the reflective film RF may include M pairs of first and second layers having different refractive indices (M is an integer greater than or equal to 2) to serve as distributed Bragg reflectors (DBR). In embodiments, the M first layers and the M second layers may be alternately provided. The first layer and the second layer may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The third capping layer CAP3 may be on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, such as silicon nitride (SiNₓ), silicon oxide nitride (SiON), silicon oxide (SiOₓ), titanium oxide (TiOₓ), and/or aluminum oxide (AlOₓ). The first light conversion layer QDL1, the second light conversion layer QDL2, and the light transmission layer TPL may be encapsulated by the first capping layer CAP1, the second capping layer CAP2, and the third capping layer CAP3.

A fourth organic layer 213 may be on the second capping layer CAP2. A plurality of color filters CF1, CF2, and CF3 may be on the fourth organic layer 213. The plurality of color filters CF1, CFb, and CF3 may include first color filters CF1, second color filters CF2, and third color filters CF3.

The first color filter CF1 on the first sub-pixel SPX1 may transmit first light (light in a red wavelength band) and absorb or block third light (light in a blue wavelength band). Therefore, the first color filter CF1 may transmit the first light (light in the red wavelength band) converted by the first light conversion layer QDL1 among the third light (light in the blue wavelength band) emitted from the light emitting element LE and absorb or block the third light (light in the blue wavelength band) not converted by the first light conversion layer QDL1. Accordingly, the first sub-pixel SPX1 may emit the first light (light in the red wavelength band).

The second color filter CF2 arranged in the second sub-pixel SPX2 may transmit the second light (light in the green wavelength band) and absorb or block the third light (light in the blue wavelength band). Therefore, the second color filter CF2 may transmit the second light (light in the green wavelength band) converted by the first light conversion layer QDL1 among the third light (light in the blue wavelength band) emitted from the light emitting element LE and absorb or block the third light (light in the blue wavelength band) not converted by the first light conversion layer QDL1. Accordingly, the second sub-pixel SPX2 may emit the second light (light in the green wavelength band).

The third color filter CF3 provided in the third sub-pixel SPX3 may transmit the third light (light in the blue wavelength band). Therefore, the third color filter CF3 may transmit the third light (light in the blue wavelength band) emitted from the light emitting element LE that passes through the light transmission layer TPL. Accordingly, the third sub-pixel SPX3 may emit the third light (light in the blue wavelength band).

The first color filter CF1, the second color filter CF2, and the third color filter CF3 that overlap in the third direction DR3 may overlap the light blocking layer BM in the third direction DR3.

A fifth organic film 214 for planarization may be on the plurality of color filters CF1, CF2, and CF3.

In another embodiment, the plurality of color filters CF1, CF2, and CF3 may be omitted.

The fourth organic layer 213 and the fifth organic film 214 may be formed from an acrylic resin, an epoxy resin, a phenolic resin, a polyamide resin, a polyimide resin, and/or the like.

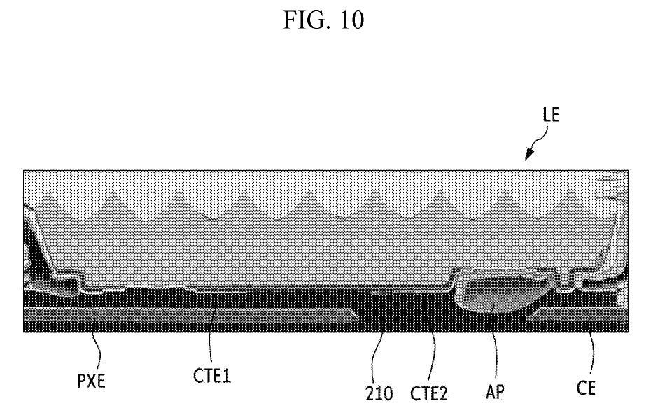

FIG. 10 is a photograph of a light emitting element having a single hole.

Referring to FIG. 10, the light emitting element LE has a single hole LEH that overlaps the second contact electrode CTE.

The light emitting element LE is on top of the pixel electrode PXE and the common electrode CE.

The light emitting element LE has a first organic layer 210 between the pixel electrode PXE and the common electrode CE.

The light emitting element LE may form an air pocket AP inside the hole LEH due to shrinkage and/or deformation caused by stress during the bonding process (and/or for other reasons). The air pocket AP formed in this way may weaken the adhesive strength between the light emitting element LE and the first organic layer 210, thereby reducing reliability. Also, the presence of air pockets AP may lead to uneven thermal conductivity, which may accelerate deterioration and performance degradation of the element if (e.g., when) used for a long time.

In the embodiments of FIGS. 7-9, by forming a plurality of small holes for contact between the second contact electrode CTE and the second semiconductor layer SEM2, the possibility of forming an air pocket AP may be reduced or minimized. Accordingly, the adhesive strength between the light emitting element LE and the first organic layer 210 may be improved, and further, deterioration and performance degradation of the element may be prevented or reduced.

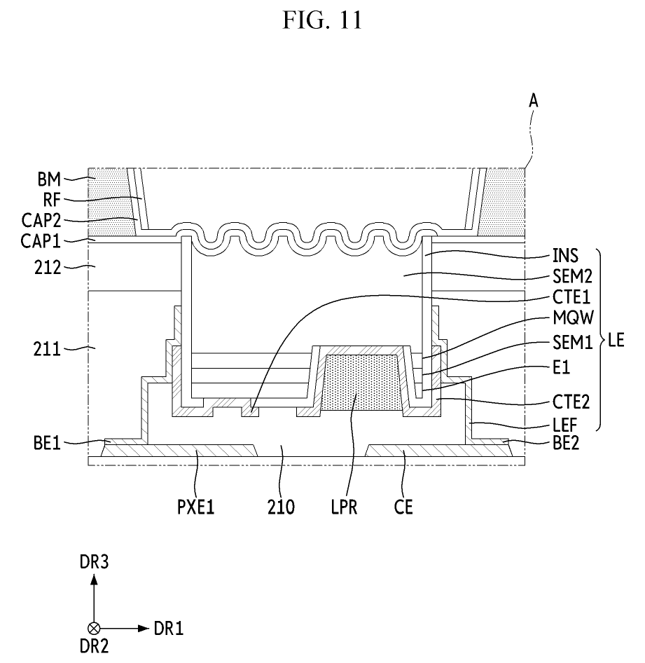

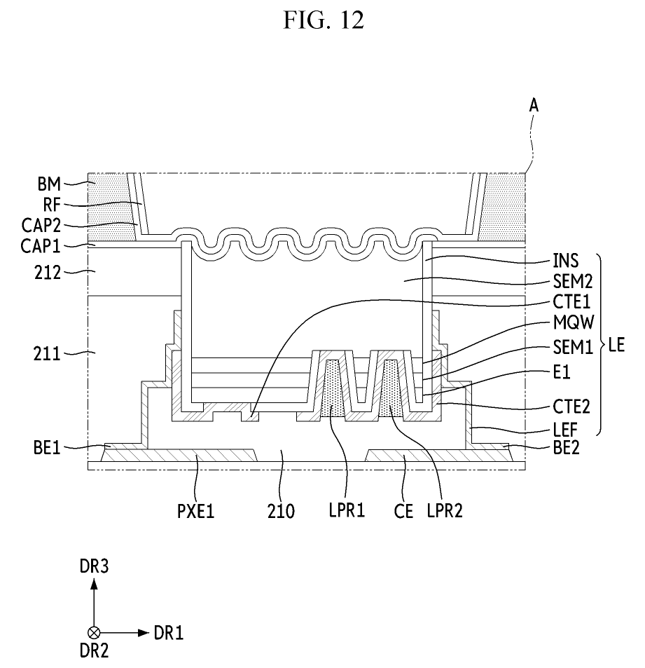

FIGS. 11 and 12 are enlarged views illustrating another example of the A area of FIG. 6 in more detail. The embodiment of FIG. 11 is different from the embodiment of FIG. 7 in that the hole LEH of the light emitting element LE is formed as one and the inside of the hole LEH is filled with an organic filler LPR. In FIG. 11, the overlapping description with the embodiment described with reference to FIGS. 6 and 7 will not be repeated, and the difference from the embodiment of FIG. 7 will be mainly described.

Referring to FIG. 11, the light emitting element LE fills the inside of the hole LEH surrounded by the second contact electrode CTE2 with a filler LPR. The filler LPR may be an organic material. The filler LPR may be the same material as the first organic layer 210 but is not limited thereto. Because the organic filler LPR fills the inside of the hole LEH, formation of air pockets inside the hole LEH is prevented or reduced, thereby maintaining uniform (e.g., substantially uniform) properties of the element.

The embodiment of FIG. 12 is different from the embodiment of FIG. 7 in that the organic filler LPR is filled inside the plurality of holes LEH1 and LEH2 of the light emitting element LE. In FIG. 11, the description overlapping with the embodiment described with reference to FIGS. 6 and 7 will not be repeated, and the description will be focused on the differences from the embodiment of FIG. 7.

Referring to FIG. 12, the light emitting element LE fills the inside of the plurality of holes LEH1 and LEH2 surrounded by the second contact electrode CTE2 with the filler LPR. The filler LPR may be an organic material. The filler LPR may be the same material as the first organic layer 210 but is not limited thereto. Because the organic filler LPR fills the interior of the plurality of holes LEH1 and LEH2, formation of air pockets inside the plurality of holes LEH1 and LEH2 is prevented or reduced, thereby maintaining uniform (e.g., substantially uniform) properties of the element.

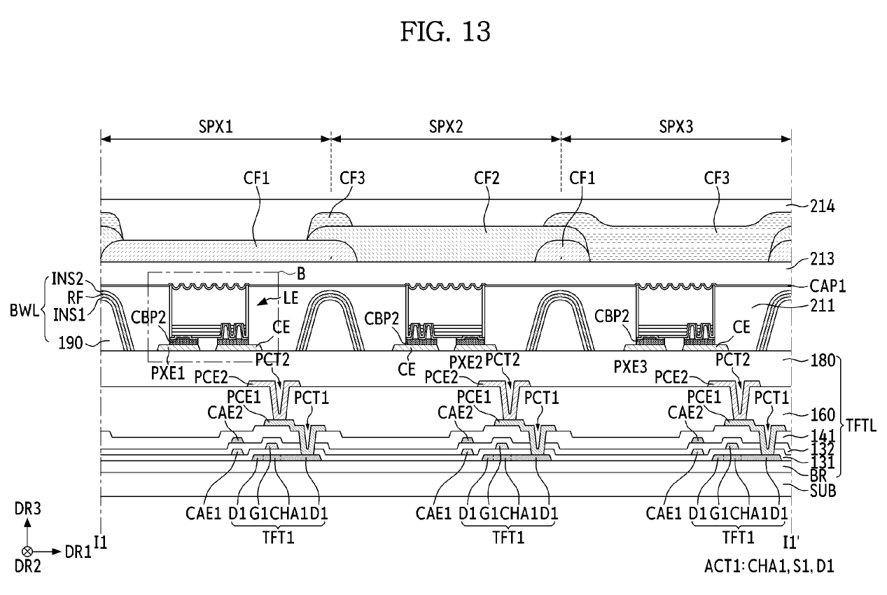

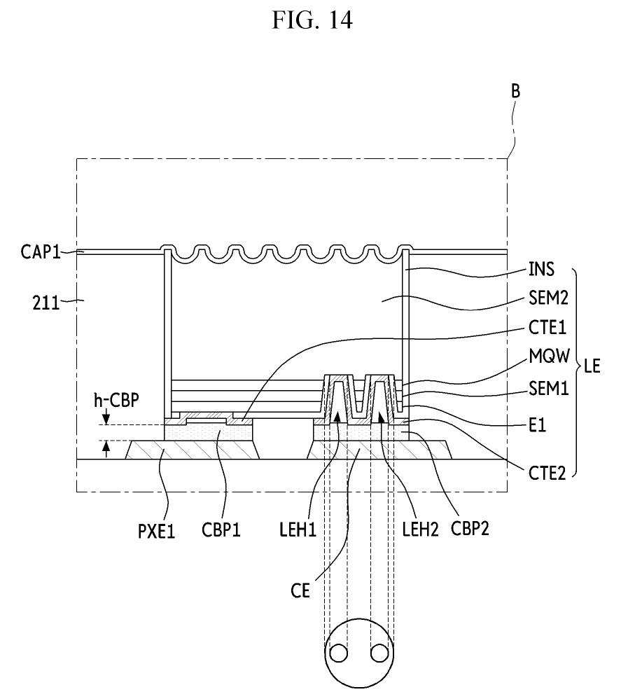

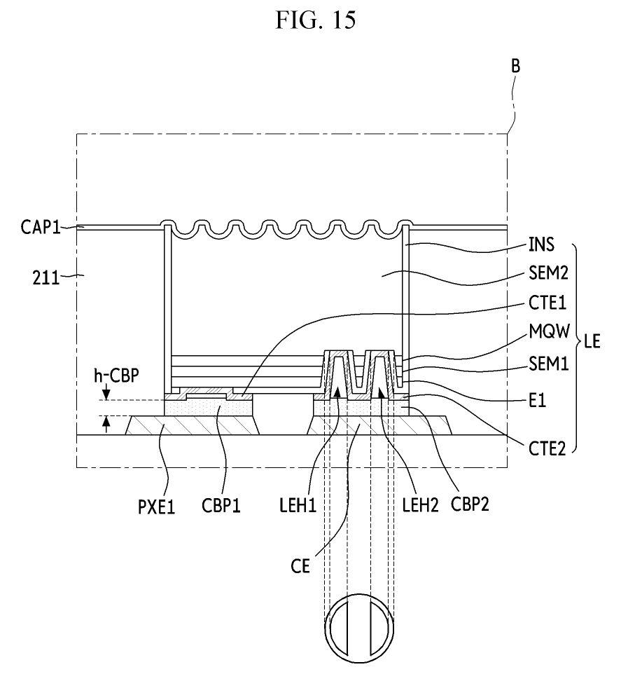

FIG. 13 is a cross-sectional view illustrating another example of the cross-section of the display panel corresponding to the line I-I’ of FIG. 5. FIG. 14 is a cross-sectional view illustrating an embodiment of the B area of FIG. 13 in more detail. FIG. 15 is a cross-sectional view illustrating an embodiment of the B area of FIG. 13 in more detail according to another embodiment.

The embodiments of FIGS. 13 and 14 differ from the embodiments of FIGS. 6 and 7 in that the structure of the light emitting element layer is different (e.g., instead of the first organic layer 210 under the light emitting element LE, conductive bonding patterns CBP1 and CBP2 are provided and the connection electrodes BE1 and BE2 are omitted) and the light blocking layer BM, the first light conversion layer QDL1, the second light conversion layer QDL2, and the light transmission layer TPL are not on the light emitting element layer. In FIGS. 9 and 10, the description overlapping with the embodiments of FIGS. 6 and 7 will be omitted, and the differences from the embodiments of FIGS. 13 and 14 will be mainly described.

Referring to FIGS. 13 and 14, the light emitting element layer may be on the second planarization organic film 180. The light emitting element layer may include pixel electrodes PXE1, PXE2, and PXE3, light emitting elements LE, a common electrode CE, conductive bonding patterns CBP1 and CBP2, and a reflective partition wall BWL. The conductive bonding patterns CBP1 and CBP2 may include a first conductive bonding pattern CBP1 and a second conductive bonding pattern CBP2.

The first conductive bonding pattern CBP1 and the second conductive bonding pattern CBP2 may include a polymer resin and conductive nanoparticles CP dispersed in the polymer resin. The conductive nanoparticles CP are conductive (e.g., electrically conductive) particles having a particle size of 100 nm or less. The resistance (e.g., electrical resistance) of the conductive nanoparticles CP is 1 ohm or less. In one embodiment, the conductive nanoparticles CP may be conductive carbon black but is not limited thereto. In addition to carbon black, the conductive nanoparticles CP may include at least one selected from the first materials selected from the group consisting of acetylene black, artificial graphite, natural graphite, copper powder, nickel powder, aluminum powder, indium powder, silver powder, and polyphenylene.

The polymer resin may be a photosensitive resin PR but is not limited thereto. The photosensitive resin PR may be an insulating material (e.g., an electrically insulating material). The photosensitive resin PR may be an acrylic resin and/or a polyimide resin. The first conductive bonding pattern CBP1 and the second conductive bonding pattern CBP2 may be patterned using a photolithography process but are not limited thereto. The first conductive bonding pattern CBP1 and the second conductive bonding pattern CBP2 may also be finely patterned and thus may be applied to a high-brightness display panel.

A light emitting element LE is on the first conductive bonding pattern CBP1 and the second conductive bonding pattern CBP2.

The light emitting element LE differs from the light emitting element LE described in the embodiment of FIG. 7 in that the first contact electrode CTE1 and the second contact electrode CTE2 are not on the side of the light emitting element LE.

A plurality of holes LEH1 and LEH2 may be formed to penetrate a conductive layer E1, a first semiconductor layer SEM1, and an active layer MQW of a light emitting element LE and expose a second semiconductor layer SEM2. The plurality of holes LEH1 and LEH2 may include a first hole LEH1 and a second hole LEH2. The first hole LEH1 and the second hole LEH2 may be symmetrical to each other and may have the same shape and the same size. Each of the first hole LEH1 and the second hole LEH2 may be circular (e.g., substantially circular) in a plane and may be provided symmetrically to each other. The first hole LEH1 and the second hole LEH2 may be formed as a single layer, but is not limited thereto, and may have a multilayer structure. A set or certain thickness difference may exist between the layers of the multilayer structure. For example, as the holes LEH1 and LEH2 become deeper, e.g., toward the inner side of the hole, a width W-LEH of the holes LEH1, LEH2 may narrow, e.g., the inner wall surface may have a slope. The first hole LEH1 and the second hole LEH2 may have a trapezoidal shape in cross section. However, the embodiment is not limited thereto, and the width of the holes LEH1 and LEH2 may have a constant (e.g., substantially constant) rectangular shape.

Each of the first hole LEH1 and the second hole LEH2 may have a circular (e.g., substantially circular) planar shape as shown in FIG. 14, but the embodiment of the present disclosure is not limited thereto.

In another embodiment, as shown in FIG. 15, each of the first hole LEH1 and the second hole LEH2 may have a semicircular shape in a plane and may be provided symmetrically based on the center line of one circle. The radius of curvature of each of the first hole LEH1 and the second hole LEH2 may be a portion of a circle (e.g., substantially a circle). Further, the plurality of holes LEH1 and LEH2 may have a planar shape of a polygon, such as an ellipse or a square (e.g., substantially an ellipse or substantially a square).

Referring again to FIGS. 13 and 14, the first contact electrode CTE1 of the light emitting element LE may be on one surface of the conductive layer E1. Therefore, the first contact electrode CTE1 may be electrically connected to the conductive layer E1.

The second contact electrode CTE2 may be on one surface of the conductive layer E1 and spaced apart from the first contact electrode CTE1. The second contact electrode CTE2 may be on the protective film INS provided in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 of the light emitting element LE may be on the first conductive bonding pattern CBP1, and the second contact electrode CTE2 may be on the second conductive bonding pattern CBP2.

The first conductive bonding pattern CBP1 and the second conductive bonding pattern CBP2 may be melted at a temperature less than 200 degrees (e.g., °C), for example, 140 degrees (e.g., °C), to bond the light emitting elements LE to the corresponding pixel electrodes PXE1, PXE2, and PXE3 and the common electrode CE.

At least a portion of the first contact electrode CTE1 and the second contact electrode CTE2 may be buried within the conductive bonding patterns CBP1 and CBP2. For example, the first contact electrode CTE1 may be partially buried in the first conductive bonding pattern CBP1, and the second contact electrode CTE2 may be partially buried in the second conductive bonding pattern CBP2.

A thickness (height) of the first conductive bonding pattern CBP1 and a thickness (height) of the second conductive bonding pattern CBP2 are the same. The thickness (height) of the first conductive bonding pattern CBP1, for example, a distance h-CBP between the interface between the conductive bonding pattern CBP and the corresponding pixel electrodes PXE1, PXE2, and PXE3 and the interface between the conductive bonding pattern CBP and the contact electrode CTE of the corresponding light emitting element LE, is about 1 µn or less.

The first conductive bonding pattern CBP1 is on the top surface of the pixel electrodes PXE1, PXE2, and PXE3 to electrically connect the pixel electrodes PXE1, PXE2, and PXE3 and the light emitting element LE. The second conductive bonding pattern CBP2 is on the top surface of the common electrode CE to electrically connect the common electrode CE and the light emitting element LE. Therefore, there is no need to form a first connection electrode (BE1 in FIG. 7) to electrically connect the pixel electrodes PXE1, PXE2, and PXE3 and the light emitting element LE and a second connection electrode (BE2 in FIG. 7) to electrically connect the common electrode CE and the light emitting element LE.

The reflective partition wall BWL is on the second planarization organic film 180 and may surround the light emitting element LE in a plane.

The reflective partition wall BWL may include, but is not limited to, a first organic layer 190 that defines the shape of the partition wall, a first protective film INS1 that covers the first organic layer 190, a reflective film RF, and a second protective film INS2. For example, at least one selected from the first protective film INS1 and the second protective film INS2 may be omitted.

The first organic layer 190 may be formed of an organic material such as an acrylic resin, an epoxy resin, a phenolic resin, a polyamide resin, a polyimide resin, and/or the like.

The first protective film INS1 is provided outside the first organic layer 190. The first protective film INS1 may cover the entire first organic layer 190.

The reflective film RF is provided outside the first protective film INS1.

The second protective film INS2 is on top of the reflective film RF. The reflective film RF is surrounded by the first protective film INS1 and the second protective film INS2.

The reflective film RF may be spaced apart from the light emitting element LE in a plane and may have a closed loop shape that surrounds the sides of the light emitting element LE. The upper end of the reflective film RF may be provided higher than the active layer MQW of the light emitting element LE. The lower end of the reflective film RF may be provided lower than the conductive layer E1 of the light emitting element LE. The reflective film RF may include a metal material having a high reflectivity, such as aluminum (Al).

The reflective film RF may be a closed loop shape that is spaced apart from the light emitting element LE in a plane and surrounds the side of the light emitting element LE. The top of the reflective film RF may be provided higher than the active layer MQW of the light emitting element LE. The bottom of the reflective film RF may be provided lower than the light emitting element LE. The reflective film RF may include a metal material having high reflectivity, such as aluminum (Al).

The first protective film INS1 and the second protective film INS2 may be formed of an inorganic layer such as silicon nitride (SiNₓ), silicon oxide nitride (SiON), silicon oxide (SiOₓ), titanium oxide (TiOₓ), and/or aluminum oxide (AlOₓ).

Because the reflective partition wall BWL includes a reflective layer, even if (e.g., when) the light emitting element LE does not have a separate reflective film, the light emitted from the side of the light emitting element LE is reflected to the front by the reflective partition wall BWL, thereby improving the light emission efficiency of the display panel 100.

A first capping layer CAP1 may be on the light emitting element LE. The first capping layer CAP1 may serve to encapsulate the underlying component.

A fourth organic layer 213 may be on the first capping layer CAP1. A plurality of color filters CF1, CF2, and CF3 may be on the fourth organic layer b. The plurality of color filters CF1, CF2, and CF3 may include first color filters CF1, second color filters CF2, and third color filters CF3.

A fifth organic film 214 for planarization may be placed on a plurality of color filters CF1, CF2, and CF3.

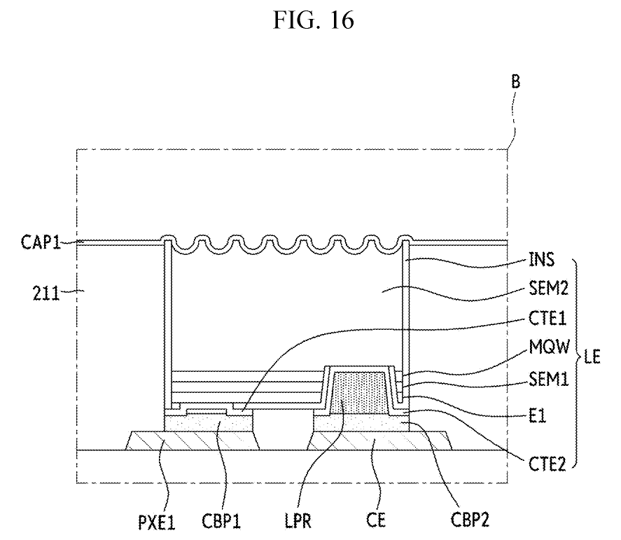

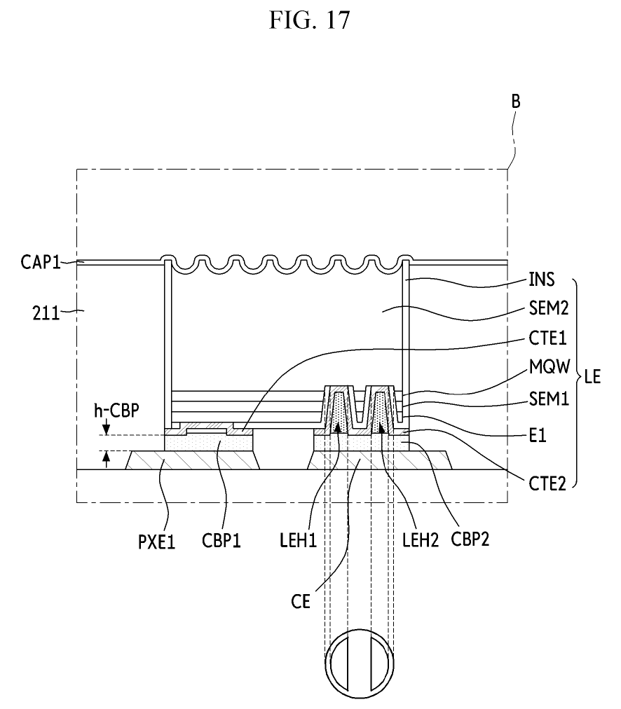

FIGS. 16 and 17 are enlarged views illustrating another example of the B area of FIG. 13 in more detail. The embodiment of FIG. 16 is different from the embodiment of FIG. 14 in that the hole LEH of the light emitting element LE is formed as one and the inside of the hole LEH is filled with an organic filler LPR. In FIG. 16, the overlapping description with the embodiment described with reference to FIGS. 13 and 14 will not be repeated, and the differences from the embodiment of FIG. 14 will be mainly described.

Referring to FIG. 16, the light emitting element LE fills the inside of the hole LEH surrounded by the second contact electrode CTE2 with a filler LPR. The filler LPR may be a conductive organic material (e.g., an electrically conductive organic material). The filler LPR may be the same material as the conductive bonding pattern CBP but is not limited thereto. Because the filler LPR fills the inside of the hole LEH, it is possible to prevent or reduce formation of air pockets inside the hole LEH, thereby maintaining uniform (e.g., substantially uniform) properties of the element.

The embodiment of FIG. 17 is different from the embodiment of FIG. 7 in that the organic filler LPR is filled inside the plurality of holes LEH1 and LEH2 of the light emitting element LE. In FIG. 11, the description overlapping with the embodiment described with reference to FIGS. 6 and 7 will not be repeated, and the description will be focused on the differences from the embodiment of FIG. 7.

Referring to FIG. 17, the light emitting element LE fills the inside of the hole LEH surrounded by the second contact electrode CTE2 with the fillers LPR1 and LPR2. The fillers LPR1 and LPR2 may be a conductive organic material (e.g., an electrically conductive organic material). The fillers LPR1 and LPR2 may be the same material as the conductive bonding pattern CBP but is not limited thereto. Because the fillers LPR1 and LPR2 fill the interior of the plurality of holes LEH1 and LEH2, formation of air pockets inside the plurality of holes LEH1 and LEH2 is prevented or reduced, thereby maintaining uniform (e.g., substantially uniform) properties of the element.

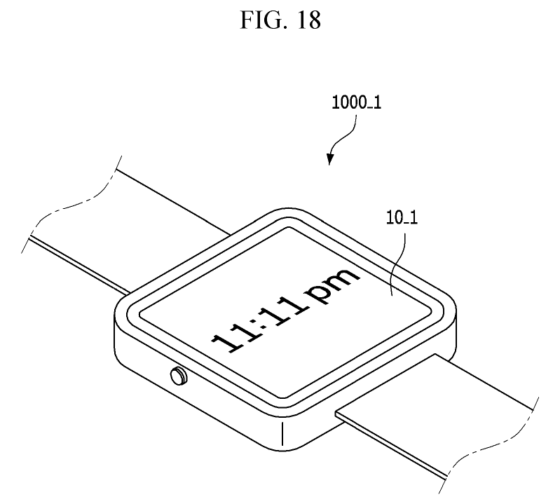

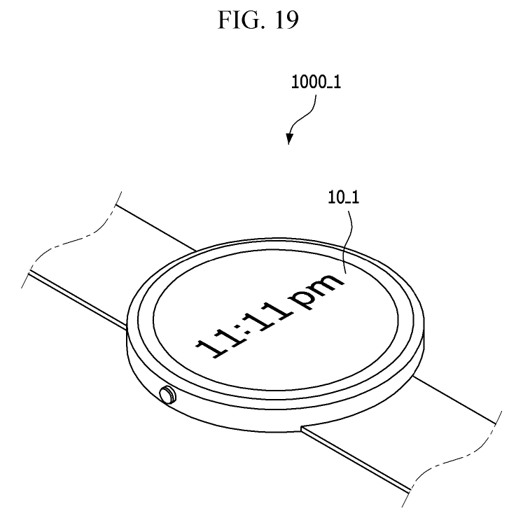

FIGS. 18 and 19 are example drawings illustrating a smart watch including a display device according to one embodiment.

Referring to FIGS. 18 and 19, a display device 10_1 according to one embodiment may be applied to a smart watch 1000_1, which is one of kind of smart device.

The flat shape of the display device 10_1 may be a square or a circle (e.g., substantially a square or substantially a circle) but is not limited thereto and may be modified in various suitable ways, such as an oval (e.g., substantially an oval).

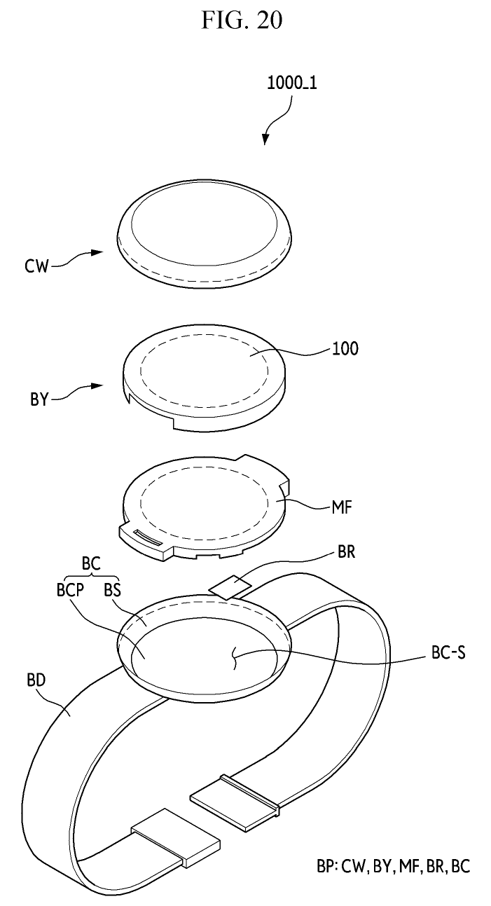

FIG. 20 is an exploded perspective view of a smart watch including a display device according to one embodiment.

Referring to FIG. 20, the smart watch 1000_1 may include a main body unit BP and a wearable portion BD.

The main body unit BP may include a display panel 100 on which an image is displayed, a cover window CW on the display panel 100, a bottom cover BC under the display panel 100, a middle frame MF between the cover window CW and the bottom cover BC, and a battery BR between the middle frame MF and the bottom cover BC. In addition to the battery BR, a main processor to control the smart watch 1000_1, a communication chipset to wirelessly communicate with the outside, and a circuit board in which memory, and/or the like are mounted may be additionally between the middle frame MF and the bottom cover BC.

The main body unit BP may sequentially include a bottom cover BC, a battery BR, a middle frame MF, a display panel 100, and a cover window CW.

The cover window CW is on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic (e.g., polymer) material, a glass material, and/or a reinforced glass material.

The cover window CW may overlap the display panel 10 and cover the front of the display panel 10. The cover window CW generally has a shape similar to that of the display panel 10 in terms of a plane, but its size may be larger than that of the display panel 10. For example, the cover window CW may protrude outward from the display panel 10. The planar shape of the cover window CW may be the same as that of the main body unit BP. For example, the planar shape of the cover window CW may be generally circular but is not limited thereto and may have various suitable shapes, for example, a polygon such as a square or an oval.

The middle frame MF is a joining member that joins the cover window CW and the bottom cover BC and is between the cover window CW and the bottom cover BC. For example, the middle frame MF may include a bracket.

The bottom cover BC is a housing provided under the display panel 10.

The bottom cover BC may include a central cover portion BCP and a peripheral portion BS provided around the central cover portion BCP.

The central cover portion BCP is provided at the center of the bottom cover BC and may be generally flat.

The peripheral portion BS may surround the central cover portion BCP. The peripheral portion BS may be a portion that is bent and curved from the central cover portion BCP. The peripheral portion BS may be bent from the edge of the central portion CP. In some embodiments, the peripheral portion BS may include a curved surface having a set or predetermined curvature, and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor and/or the like is mounted. The display device 10_1 may be electrically connected to the circuit board to receive digital video signals, timing signals, power, and/or the like.

The bottom cover BC is placed on the outermost rear surface of the electronic device and may include at least one selected from a plastic (e.g., polymer) material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion that fixes the main body unit BP to the user's wrist, for example, and may be one of a strap, a chain, and/or a bracelet.

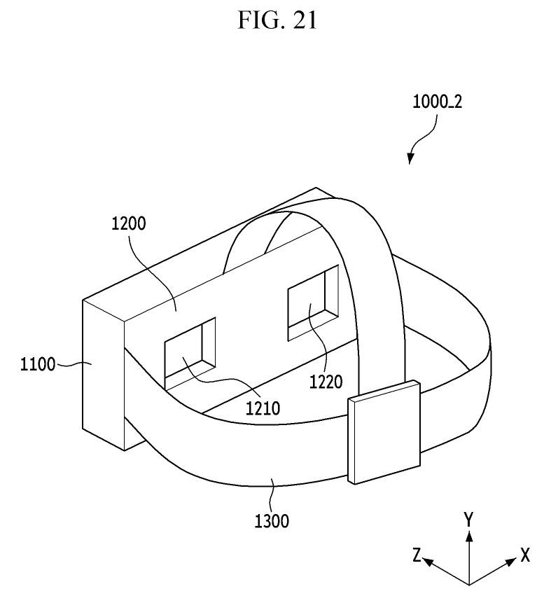

FIG. 21 is an example view of a virtual reality (VR) device including a display device according to one or more embodiments.

Referring to FIG. 21, a head mounted display device 1000_2 according to one or more embodiments include a display device housing 1100, a housing cover 1200, a first eyepiece 1210, a second eyepiece 1220, and head mounted band 1300.

The display device housing 1100 houses a display device. A head mounted display device 1000_2 according to one or more embodiments further include a first optical member between the first display device 10_2 and the first eyepiece 1210.

The housing cover 1200 covers an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are provided separately in FIG. 21, the present disclosure is not limited thereto. The first eyepiece 1210 and the second eyepiece 1220 may also be combined into one.

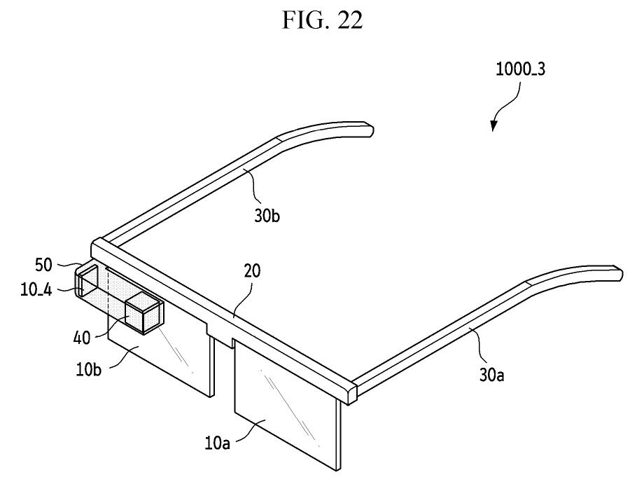

The head mounted band 1300 fixes the display device housing 1100 to a user’s head so that the first eyepiece 1210 and the second eyepiece 1220 of the housing cover 1200 are kept placed on the user’s left and right eyes, respectively. If (e.g., when) the display device housing 1200 is implemented to be lightweight and small, the head mounted display device 1000_2 may include an eyeglass frame as illustrated in FIG. 22 instead of the head mounted band 1300.

The display device housing 1100 houses display device. In embodiments, the head mounted display device 1000_2 may further include a battery for supplying power, an external memory slot that accommodates an external memory, and an external connection port and a wireless communication module that receives an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

FIG. 22 is an example view of a VR device including a display device according to one or more embodiments. FIG. 22 illustrates a VR device 1000_3 to which a display device 10_4 according to one or more embodiments has been applied.

Referring to FIG. 22, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 22, an embodiment where the VR device 1000_3 is a glasses-type display device including the eyeglass frame legs 30a and 30b is illustrated as an example. For example, the VR device 1000_3 according to the embodiment is not limited to the one illustrated in FIG. 31 and can be applied in various suitable forms to various suitable other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is provided at a right end of the support frame 20 in FIG. 22, the present disclosure is not limited thereto. For example, the display device housing 50 may also be provided at a left end of the support frame 20. In embodiments, an image displayed on the display device 10_4 may be reflected by the reflective member 40 and provided to the user’s left eye through the left lens 10a. Accordingly, the user may view a VR image displayed on the display device 10_4 through the left eye. In embodiments, the display device housing 50 may be provided at both the right end and the left end of the support frame 20. In embodiments, the user may view a VR image displayed on the display device 10_4 through both the left eye and the right eye.

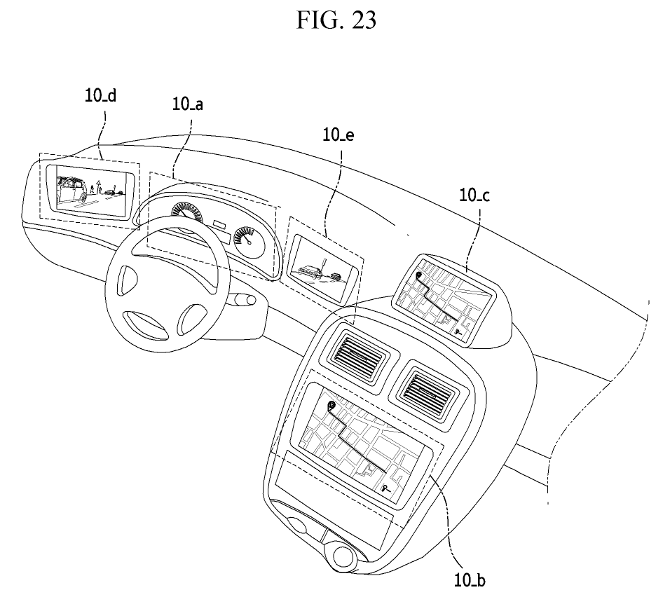

FIG. 23 is an example view illustrating a vehicle instrument cluster and center fascia including display devices according to one or more embodiments. FIG. 23 illustrates a vehicle to which display devices 10_a through 10_e according to one or more embodiments have been applied.

Referring to FIG. 23, the display devices 10_a through 10_c according to the embodiment may be applied to an instrument cluster of the vehicle, a center fascia of the vehicle, and/or a center information display (CID) on a dashboard of the vehicle. In embodiments, the display devices 10_d and 10_e according to the embodiment may be applied to room mirror displays that replace side mirrors of the vehicle.

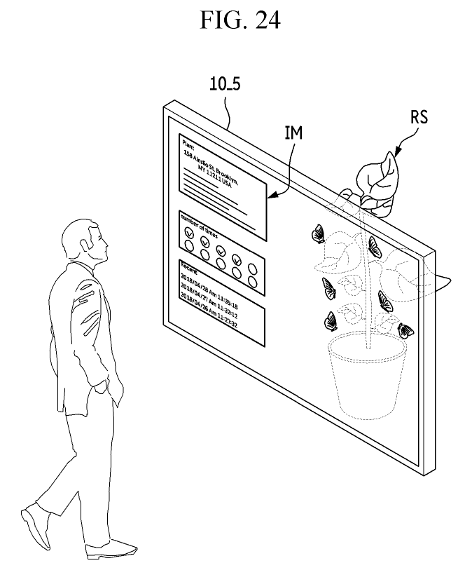

FIG. 24 is an example view of a transparent display device including a display device according to one or more embodiments.

Referring to FIG. 24, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. If (e.g., when) the display device 10_5 is applied to the transparent display device, a substrate of the display device 10_5 may include a light transmitting portion that can transmit light or may be made of a material that can transmit light.

It should be understood, however, that aspects and features of embodiments of the present disclosure are not restricted to the one set forth herein. The above and other aspects of embodiments of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode and a common electrode spaced apart from each other on the substrate;
a first organic layer that covers at least a portion of the pixel electrode and the common electrode; and
a light emitting element on the first organic layer and comprising a conductive layer, a first semiconductor layer, an active layer, a second semiconductor layer, a first contact electrode, and a second contact electrode,
wherein the light emitting element further comprises,
a plurality of holes that penetrate the conductive layer, the first semiconductor layer, and the active layer to expose the second semiconductor layer,
wherein the first contact electrode is electrically connected to the conductive layer, and
wherein the second contact electrode is electrically connected to the exposed second semiconductor layer.

2. The display device of claim 1, wherein the light emitting element further comprises a protective layer that surrounds a side surface of the conductive layer, the first semiconductor layer, the active layer, and the second semiconductor layer, and on one side of the conductive layer, and comprising a plurality of openings on one side of the conductive layer,
wherein the first contact electrode is on the conductive layer exposed by an opening of the protective layer, and
wherein the second contact electrode is provided inside a hole exposed by the opening of the protective layer.

3. The display device of claim 2, wherein the first contact electrode and the second contact electrode each extend from one side of the light emitting element to a side surface of the light emitting element, and
further include a first connection electrode connection the pixel electrode and the first contact electrode, and a second connection electrode connection the common electrode and the second contact electrode.

4. The display device of claim 3, wherein the first contact electrode directly contacts the first connection electrode on a side of the plurality of semiconductor layers, and the second contact electrode directly contacts the second connection electrode on the side of the plurality of semiconductor layers.

5. The display device of claim 1, wherein the plurality of holes comprise a first hole and a second hole, and
wherein the first hole and the second hole are circular, semicircular, or polygonal in a plane.

6. The display device of claim 5, wherein the first hole and the second hole are symmetrical to each other.

7. The display device of claim 1, further comprising a filler made of an organic material filled in the hole.

8. A display device comprising:
a substrate;
a pixel electrode and a common electrode spaced apart from each other on the substrate;
a first conductive bonding pattern on the pixel electrode and a second conductive bonding pattern on the common electrode;
a light emitting element on the first conductive bonding pattern and the second conductive bonding pattern, and comprising a conductive layer, a first semiconductor layer, an active layer, and a second semiconductor layer, a first contact electrode, and a second contact electrode,
wherein the light emitting element further comprises,
a plurality of holes that penetrate the conductive layer, the first semiconductor layer, and the active layer to expose the second semiconductor layer,
wherein the first contact electrode is electrically connected to the conductive layer, and
wherein the second contact electrode is electrically connected to the exposed second semiconductor layer.

9. The display device of claim 8, wherein the light emitting element further comprises a protective layer that surrounds a side surface of the conductive layer, the first semiconductor layer, the active layer, and the second semiconductor layer, and on one side of the conductive layer, and comprising a plurality of openings on one side of the conductive layer,
wherein the first contact electrode is on the conductive layer exposed by an opening of the protective layer, and
wherein the second contact electrode is provided inside a hole exposed by the opening of the protective layer.

10. The display device of claim 8, wherein the plurality of holes comprise a first hole and a second hole, and
wherein the first hole and the second hole are circular, semicircular, or polygonal in a plane.

11. The display device of claim 10, wherein the first hole and the second hole are symmetrical to each other.

12. The display device of claim 8, comprising a filler filled in the hole.

13. The display device of claim 12, wherein the filler is a conductive organic filler, a metal, or a combination thereof.

14. The display device of claim 8, wherein the first conductive bonding pattern and the second conductive bonding pattern each comprise a polymer resin and conductive nanoparticles dispersed in the polymer resin.

15. The display device of claim 14, wherein the conductive nanoparticles comprise conductive carbon black.

16. The display device of claim 8, wherein a height of the first conductive bonding pattern and the height of the second conductive adhesive pattern are each 1 μm or less.

17. The display device of claim 8, further comprising a reflective partition wall that surrounds the light emitting element in a plane,
wherein the reflective partition wall comprises,
an organic layer that defines a shape of the reflective partition wall; and
a reflective layer on the organic layer.

18. The display device of claim 17, wherein a top surface of the reflective partition wall is provided lower than a top surface of the light emitting element.

19. An electronic device comprising:
a display panel;
a window on the display panel; and
a bottom cover provided below the display panel,
wherein the display panel comprises,
a substrate;
a pixel electrode and a common electrode spaced apart from each other on the substrate;
a first organic layer that covers at least a portion of the pixel electrode and the common electrode; and
a light emitting element on the first organic layer and comprising a conductive layer, a first semiconductor layer, an active layer, a second semiconductor layer, a first contact electrode, and a second contact electrode,
wherein the light emitting element further comprises,
a plurality of holes that penetrates the conductive layer, the first semiconductor layer, and the active layer to expose the second semiconductor layer,
wherein the first contact electrode is electrically connected to the conductive layer, and
wherein the second contact electrode is electrically connected to the exposed second semiconductor layer.

20. The electronic device of claim 19, further comprising a battery provided in a space of the bottom cover and that supplies power to the display device; and
a middle frame between the window and the bottom cover.
